(19) United States
(12) Patent Application Publication
(10) Pub. No.: US 2021/0255543 A1
(43) Pub. Date: Aug. 19, 2021

(54) A SINGLE STEP LITHOGRAPHY COLOUR FILTER

(71) Applicant: Cambridge Enterprise Limited, Cambridgeshire (GB)

(72) Inventors: Calum Williams, Cambridge (GB); George Gordon, Cambridge (GB); Timothy Wilkinson, Cambridge (GB); Sarah Bohndiek, Cambridge (GB)

(21) Appl. No.: 17/251,064

(22) PCT Filed: Jun. 13, 2019
(86) PCT No.: PCT/GB2019/051645

§ 371 Date: Dec. 10, 2020

(30) Foreign Application Priority Data
Jun. 14, 2018 (GB) 1809748.5

(51) Int. Cl. G03F 7/00; G02B 5/26

(52) U.S. Cl. CPC G03F 7/0007; H01L 27/14621; G03F 7/0002; G02B 5/26

(57) ABSTRACT

A method is provided of producing an optical filter. The method comprises depositing a first mirror layer onto a substrate; depositing an insulating layer on the first mirror; exposing at least some of a plurality of portions of a surface of the insulating layer to a dose of energy; developing the insulating layer in order to remove a volume from the at least some of the plurality of portions of the insulating layer, wherein the volume of the insulating layer removed from each portion is related to the dose of energy exposed to each portion, and wherein a remaining thickness after the removal of the volume from each portion of the insulating layer is related to the dose of energy exposed to each portion. The method further comprises depositing a second mirror layer on the remaining thickness of each of the plurality of portions of the insulating layer.

### FIELD

This specification generally relates to optical colour filters, particularly but not exclusively, to multi-spectrum colour filters having three-dimensional physical structures, and their fabrication methods.

### BACKGROUND

Converting optical information (light) to electronic information (electrons) lies at the heart of every digital image sensor. Complementary metal-oxide-semiconductor (CMOS) image sensors which are cheap, compact and efficient are now considered ubiquitous. CMOS sensors are implemented in a range of applications from digital photography to medical imaging. Typically, the image sensor is composed of millions of individually addressed silicon photodetectors. To detect colour (a specific optical wavelength), spatially variant spectrally distinct optical filters are required to be used in combination with the CMOS sensors. These colour filter arrays (CFAs) possess mosaic-like patterns, with pixel sizes comparable to the individual CMOS sensor dimensions, and which tessellate atop the image sensor.

Colour filter arrays (CFAs) are critical thin-film optical components used extensively for image sensors. Further alternative uses for such CFA or MSFA filters exist, for example, the direct illumination of a target to be imaged. In the known state of the art, CFAs are typically comprised of either pigment-based filters or multi-layer stacks implemented for colour filtering. Both require a variety of materials in various combinations in order to achieve wavelength discrimination within the filter. Both of these known filters also require a relatively thick filter to achieve a desirable efficacy in wavelength discrimination. Furthermore, multiple successive lithographic steps may typically be required in fabrication, dependent on the number of wavelength bands required in the colour filter.

These color filter arrays (CFAs) are deposited in mosaic-like patterns atop the image sensor with a pitch matched to the pixel size The most widespread CFA is the Bayer filter which includes red, green and blue (RGB) filters. However, more complex mosaics incorporating additional spectral filters are commonplace in multi-spectral imaging systems (for example: Lapray et al., Sensors (Switzerland) 2014, 14, 21626-21659). Referred to as multi-spectral filter arrays (MSFAs), these optical elements are generally commonplace in multiple fields of imaging applications ranging from agriculture to medical diagnostics, for example.

For conventional CMOS image sensors, the CFAs/MSFAs are typically composed of either absorptive dyes or pigments, having one dye or pigment for each colour. Alternatively, a filter may be composed of a many-layer one-dimensional Bragg stack, in which a different combination of alternating dielectric materials corresponds to each colour. However, both compositions and methods are cumbersome from a fabrication point of view. For example, for a filter having N wavelengths, N separate lithographic (or N hard mask) steps are required; one for each wavelength. Additionally, for an N wavelength filter with N material compositions, either dyes or varying combinations of alternating dielectrics in the Bragg stack are required. With carefully aligned lithographic steps required for CFA fabrication, the continual shrinking of pixel dimensions for higher resolutions, and more complex mosaic patterns to exploit added wavelength bands, the typically-used methodology is highly problematic. Moreover, due to the established CFA fabrication techniques, there is a sizeable financial cost associated with producing custom MSFAs with tailored optical characteristics.

It is further known in the art that metal-insulator-metal (MIM) geometries may provide the basis for CFAs. The MIM optical filters' material compositions can be deposited in the same processing step. However, typically in the known art, each thickness of each layer is fixed. As a result, MIM filters are typically fabricated through iterative ‘step-and-repeat’ processes, which limits their use in spatially variant MSFA applications.

Conventional cameras, such as in smartphones, capture wideband red, green and blue (RGB) spectral components, replicating human vision. Multispectral imaging (MSI) captures spatial and spectral information beyond our vision but typically requires bulky optical components and is expensive. Snapshot multispectral image sensors have been proposed as a key enabler for a plethora of MSI applications, from diagnostic medical imaging to remote sensing. To achieve low-cost and compact designs MSFAs based on thin-film optical components may be deposited atop image sensors. Conventional MSFAs achieve spectral filtering through either multi-layer stacks or pigment, requiring: complex mixtures of materials; additional lithographic steps for each additional wavelength; and large thicknesses to achieve high transmission efficiency.

Alternative popular methodologies for colour generation exist, which involve ultrathin plasmonic and high-index dielectric nanostructure arrays, whereby electric and magnetic resonance respectively can be excited (though geometry and material selection) which are wavelength and polarisation selective. However, these techniques still suffer from either low transmission efficiencies and/or broad full-width-half-maximums (FWHMs), i.e. poor wavelength selectivity. These features also render these methodologies unsuitable for multi-spectral imaging technologies.

### SUMMARY

Therefore, there remains a need in the art to provide a cost-effective and efficient method of fabrication of MSFA/CFAs involving only a single lithographic step, and which produces devices with improved optical wavelength selectivity, and improved transmission efficiencies. The following summary and detailed examples describe a single-step grayscale lithographic process that enables wafer-level fabrication of bespoke MSFAs based on Fabry-Perot type resonances of spatially variant metal-insulator-metal (MIM) cavities, where the exposure dose controls insulator (cavity) thickness.

According to one aspect of the present disclosure, there is provided a method for producing an optical filter, the method comprising: depositing a first mirror layer on a substrate; depositing an insulating layer on the first mirror layer; exposing at least some of a plurality of portions of a surface of the insulating layer to a dose of energy; developing the insulating layer in order to remove a volume from the at least some of the plurality of portions of the insulating layer, wherein the volume of the insulating layer removed from each portion is related to the dose of energy exposed to each portion, and wherein a remaining thickness after the removal of the volume from each portion of the insulating layer is related to the dose of energy exposed to each portion; depositing a second mirror layer on the remaining thickness of each of the plurality of portions of the insulating layer such that the remaining thickness of each of the plurality of portions of the insulating layer define a profile of the optical filter.

Advantageously, this method may be used for fabrication at the wafer level, and provides an optical performance and customizability which surpasses conventional nano-photonic methods. In particular, in the above method, ultra-high resolution in-plane patterning is obviated, unlike in nano-photonic counterparts.

It will be understood that each mirror may be partially optically reflective, and may also be deposited in a uniform thickness. The method also comprises exposing at least some of a plurality of portions of a surface of the insulating layer to a dose of energy, where it will be understood that it is possible that all portions of the surface of the insulator may be exposed, and also that only a select few of the portions of the surface of the insulator may be exposed. These portions of the surface of the insulator may also be referred to as pixels in this disclosure. It will further be understood that the dose of energy may be a chemically activating dose of energy, in that it may induce a chemical change in the insulator or resist material. The substrate may be a transparent layer. In other examples, the substrate may be an image sensor itself, onto which the filter may be directly disposed and/or fabricated.

The method may comprise developing the insulating layer in order to remove a volume from said at least some of the plurality of portions of the insulating layer. In other words, only the certain portions of the insulator may be developed. The volume of the insulating layer removed from each portion may be related to the dose of activating energy exposed to each portion (or pixel). Depending on the type of insulator material used, the volume removed may be roughly proportionally or roughly inversely related to the dose of activating energy exposed to each portion. It will further be understood that, corresponding to the removed volume, a remaining thickness of the insulating layer (after the removal of the volume from each portion of the insulating layer) may also be related to the dose of activating energy (or the total energy) exposed to each portion. The dose of activating energy may be a variable dose of energy, wherein the dose may be varied for each of exposed portions (that is, pixels) of insulating layer.

Furthermore, the developing of the insulating layer to remove the volume from the at least some of the plurality of portions of the insulating layer may comprise chemically developing the insulating layer, wherein the volume removed from said at least some of the plurality of portions of the insulating layer becomes chemically dissolved. The chemically dissolved layer may thus be washed away as part of the chemical development.

The method may further comprise depositing a second mirror layer on the remaining thickness of each of the plurality of portions of the insulating layer such that the remaining thickness of each of the plurality of portions of the insulating layer may define a profile of the optical filter. It will be understood that the remaining thickness is, in other words, the remaining surface of the insulator after having been developed and, after volumes have been removed from each of the exposed portions (applicable to positive or negative resist tone) of the insulating layer.

In one example, the remaining thickness after the removal of the volume from each portion of the insulating layer may be achieved by using a single step lithographic process. Therefore, it will be understood that the ability to perform an efficient single-step lithographic step bears many advantages, for example, any one or all of: lower cost, more efficient fabrication, and a very high level of device versatility and customisability. Generally, the dose of energy, for example an electron beam, may be modulated to produce a grayscale profile of arbitrary patterning, thus allowing for an advantageously efficient single-step process to produce an optical filter. The optical filters which result from such single step dose-modulated/grayscale lithographic methods may proceed MSFA filter of arbitrary complexity with the equivalent manufacturing time as simple filters, e.g. conventional Bayer filters.

In another aspect, the method of fabricating the remaining thickness after the removal of the volume from each portion of the insulating layer may be achieved by using a grayscale lithographic process. It will be further understood that, due to the versatility and precision available using the grayscale lithographic process, it may effectively allow for increasingly small and precise pixels to be fabricated in the device, resulting in an advantageously high resolution.

It will be understood that, resulting from for producing an optical filter, the remaining thickness of each portion of the insulating layer may define a two-dimensional profile of optical wavelengths, wherein the two-dimensional profile may be the an in-plane spatially varying colour profile transmitted through the optical filter. That is, the profile of remaining thicknesses of the plurality of portions of the insulating layer may produce, when incident light hits the optical filter, a corresponding profile of colours over a 2D area. Therefore, it will be further understood that the insulating layer may be optically transmissive, optically transparent, or at least optically translucent. The insulator may further be deposited in a uniform thickness. For the sake of clarity, it will be understood that the resist layer, insulator layer and resist/insulator cavity all refer to the same feature of the optical filter. It will also be understood that the term cavity does not refer to an empty space, but rather refers to the insulator/resist, which may be disposed in-between the first and second mirror layers. Advantageously, this versatile approach may require only a single lithographic processing step, and the same materials may be used for each for each wavelength band of the optical filter, making the fabrication process and resultant optical filter highly customizable.

In one example, the remaining thickness of each portion of the insulating layer (in other words, each pixel) may define a spectral (i.e. wavelength) position of the transmission peak. Further, the spectrum of light transmitted through each portion of the insulating layer (that is, transmitted through each pixel) may correspond to the spectral position. In other words, the light ultimately transmitted through each pixel may exhibit a characteristic optical wavelength profile, or range of wavelengths/colours, which in turn may correspond to the thickness of the insulator cavity in that pixel. It should be appreciated that the spectrum of light ultimately transmitted through the filter is not restricted to lying in the visible spectrum, but may extend to the near-infra-red (NIR), infra-red (IR), and ultra-violet (UV) spectrum of light. Similarly, the term optical used to describe the filters is intended to include at least the NIR, IR, and UV spectrum in addition to the visible electromagnetic spectrum of wavelengths.

Generally, it will be understood that the first mirror layer may be partially optically reflective and possesses a first uniform thickness, and also the second mirror layer may be partially optically reflective and may also be disposed in a uniform thickness.

In another example, the thickness of the first mirror layer may be varied. That is, a thicker, or narrower, first mirror layer may be disposed onto the substrate. When the rest of the device is fabricated, in which the first mirror bears the insulator and the second mirror, it will be understood that the thickness of the first mirror layer may define the breadth of the transmitted spectrum of light through each portion of the insulating layer. In other words, a thicker lower (first) mirror lay may result in a narrower, or more specific, spectrum of light being transmitted through that pixel. It will further be appreciated that a narrower spectrum may also be defined as a smaller full-width-half-maximum (FWHM). Therefore, it will also be apparent that, in correspondence with the above, a narrower first mirror layer may result in a broader spectrum of transmitted light at each pixel.

As discussed, the method may comprise exposing the insulator to a chemically activating dose of energy. In one example, the insulating layer may chemically strengthen upon being exposed to the dose of energy. For example, the resist may be an energy sensitive polymer, which may become crosslinked upon exposure to the activating dose of energy. The degree of strengthening, or crosslinking, in the polymer may alter the resultant solubility of the insulator (or cavity). Therefore, when the insulator is exposed to a chemical developer solution, the volume of the insulating layer removed from each portion may be related to the altered solubility of the insulator. In other words, the remaining thickness of insulating layer from each portion may be proportional to the dose of energy exposed at each portion. It will be apparent that this regime comprises a negative-tone resist polymer.

In one example, the insulating layer may chemically weaken upon being exposed to the dose of energy. For example, the resist may be an energy sensitive polymer, which may become chemically degraded upon exposure to the activating dose of energy. In other words, the remaining thickness of insulating layer from each portion may be inversely-proportional to the dose of energy exposed at each portion. It will be understood that this regime may comprise a positive-tone resist polymer.

It will be appreciated that the method of using the grayscale lithographic process may comprise using a beam of energy. Further, the beam of energy may be varied for the at least some of the plurality of portions. In examples, the beam of energy may comprise a beam of electrons, or the beam may comprise photons, for example a laser. It will nevertheless be appreciated that any other suitable chemically activating beam of energy may be used. For example, other lithographic techniques could be used, such as a mask-less technique including a direct write ultraviolet (UV) laser lithography (e.g. laser write), DMD (digital micro-mirror device) based lithography. In other examples, a mask-based lithography, e.g. photolithography can be used.

In an alternative example, the method may further comprise providing a mask over the insulating layer. The method may also comprise exposing the mask to a dose of chemically activating energy. For example, the dose of energy incident on the mask may be a uniform dose of energy across the surface of the mask. Additionally, the method may further comprise providing a mask over the insulating layer, wherein the dose of energy which exposes at least some of a plurality of portions of a surface of the insulating layer is transmitted through the mask.

Again, the dose of energy may be a chemically activating dose of energy. It will be understood that the mask may comprise multiple portions, where each portion may possess a variable opacity. This variable opacity may attenuate the uniform dose of activating energy to a varying degree, such that a plurality of variably attenuated energy doses may be exposed to the insulating layer. In other words, the mask may comprise a plurality of portions with each having a degree of opacity, wherein each portion of the mask attenuates the uniform dose of chemically activating energy according to said portion's degree of opacity, such that a plurality of attenuated energy doses are exposed to the insulating layer.

The method may further comprise: providing an attenuating mask over the insulating layer, the attenuating mask comprising a plurality of portions which defines an attenuation profile, wherein the dose of energy which exposes the surface of the insulating layer is transmitted through the mask and attenuated according to the attenuation profile.

The plurality of portions of the attenuating mask may possess at least two different levels of opacity, and one of the levels of opacity may be opaque or substantially opaque. That is, the attenuating mask may be a binary mask comprising opaque regions which substantially do not transmit the dose of energy, and transparent portions. The transparent portions may be arranged periodically across the mask, i.e. each separated by a uniform and repeating dimension.

The method may further comprising laterally translating the mask over the insulating layer and exposing the surface of the insulating layer to a second dose of energy, wherein the second dose of energy is transmitted through the mask and attenuated according to the attenuation profile. It will be appreciated that further lateral translations and exposures to further doses of energy may be applied.

Advantageously, in accordance with the above mask method, a grayscale profile may be attained with only a binary mask. For example, a mask comprising only opaque or transparent regions which is translated and subjected to a second dose of energy, may provide an insulating layer with three different levels of exposure, and thus 3 different resultant transmission wavelengths after development.

Further advantageously, the mask-based method of fabricating the optical filter may be performed on a larger scale, and may be produced on the wafer-level of in image sensor, and/or directly in conjunction with commercial CMOS sensors.

The mask-based method, described with reference to detailed examples in the following, has the advantage over known techniques that the present process uses a single (grayscale) lithographic step. Known (i.e. classical) lithography processes typically repeat a lithographic step many times, and possess little to not modularity/flexibility in filter design. By contrast, examples of dose/energy modulated methods described herein provide for an arbitrary range of filter designs due to the ease with which filter designs can be modulated.

It will be readily understood that the opacity of the mask refers to multiple portions (or pixels) of the mask which may each be opaque, or transparent, to varying degrees. That is, the opacity refers to the proportion of incident light that may be transmitted through the mask. Therefore, it will be apparent that the variable opacity of the plurality of portions of the mask may define the remaining thickness of each of the plurality of portions (that is, the remaining thickness of the pixel) of the insulating layer.

The feature of using the mask may be referred to as a photolithography process. This mask-based process generally involves an energy beam comprising photons, though may alternatively comprise an electron beam. The method involving the mask may further comprise chemically developing the insulating layer, in which a variable volume from the at least some of the plurality of portions of the insulating layer may become chemically dissolved and removed from each of the plurality of portions of the insulating layer. It will again be understood that the remaining thickness of the insulator may be the result of this development step, which may involve the exposure to a chemical development solution and/or de-ionized water. Therefore, in general, it will be understood that the three-dimensional optical filter device able to be fabricated may be identical when fabricated using either the grayscale lithography process or using the photolithography and mask process. It will be understood that both methods fundamentally include a single lithographic step.

In an alternative example of the method, we disclose a method which further comprises depositing a further type insulating layer over the first mirror layer. This further type insulating layer may be a more robust or resilient material, for example any variety of glass, such as quartz.

The method may further comprise depositing an insulating/resist layer on the further type insulating layer. The method may comprise exposing the at least some of the plurality of portions of the insulating layer to the dose of energy, and may further involve etching the remaining thickness of each of the plurality of portions of the insulating layer. Following this, the method may comprise developing (chemically developing as described, or other suitable development procedure) the further type insulating layer. Etching the more robust, further type of insulating layer may remove a volume from at least some of the plurality of portions of the further type insulating layer. The etching may be a dry etch and comprise heavy ion bombardment (reactive ion etching), or in other examples may comprise a wet (chemical) etch such as hydrofluoric acid.

However, the reactive ion etching step (bombardment of ionised particles) may act as a combined exposure and development step, in which the bombardment may comprise physically etching the robust insulator surface. As in other examples, the method may comprise depositing the second mirror layer on the further type insulating layer.

Another example of the method of producing an optical filter is disclosed, which comprises providing a stamping block. The method comprises: providing a stamping block; depositing a first insulating layer on the stamping block; exposing at least some of a plurality of portions of a surface of the first insulating layer to a dose of energy; and developing the first insulating layer in order to remove a volume from said at least some of the plurality of portions of the first insulating layer, wherein the volume of the first insulating layer removed from each portion is related to the dose of energy exposed to each portion, and wherein a remaining thickness after the removal of the volume from each portion of the first insulating layer is related to the dose of energy exposed to each portion. The method also comprises etching the remaining thickness of each of the plurality of portions of the first insulating layer; and wherein the step of etching the remaining thickness removes a volume from at least some of the plurality of portions of the stamping block.

The method may further comprise: depositing a first mirror layer onto a substrate; depositing a second insulating layer on the first mirror layer; applying the stamping block on the second insulating layer to imprint a pattern of the stamping block on the second insulating layer so that portions with variable thicknesses are formed in the second insulating layer. Finally, the method may comprise depositing a second mirror layer on each of the portions with variable thicknesses formed in the second insulating layer such that the second insulating layer defines a profile of the optical filter.

It will be understood that this stamping block may also be comprised of a robust or resilient material. It will be understood that a robust material may be able to withstand the effects of a chemically activating dose of energy, but may be etched by more heavy-duty methods, for example with bombardment with ionised particles. For example, the activating dose of energy may be an electron beam, which may only have sufficient energy to activate the resist/insulator layer, but not the stamping block layer. A photolithographic technique may alternatively be used, i.e. using a beam of photons and possible including a mask to attenuate the beam of photons.

It will be understood that the volume of the further insulating layer removed from each portion may be related to the dose of activating energy exposed to each portion, and thus the remaining thickness after the removal of the volume from each portion of the further insulating layer may be related to the dose of activating energy exposed to each portion. For the etching, a dry etching procedure may be used which may bombard the portions of the further insulating layer to positively charged Argon (Ar) atoms, or in other examples a wet (chemical) etch may be used. It will be further understood that the bombardment of ions may be delivered as a uniform dose exposure. The method may ultimately comprise developing the stamping block, in which a volume may be removed from at least some of the plurality of portions of the stamping block.

After the fabrication of the stamping block, which possesses a profile of varying thickness etched into its surface, it will be understood that resultant stamping block may form a master stamping dye. Therefore, one example of the method may further comprise applying the (etched) stamping block (also known as the master stamping dye) on the insulating layer. Doing so may imprint a remaining thickness of each of the plurality of portions of the insulating layer, corresponding to the pattern/profile of thicknesses which may be present on the surface of the stamping block after the etching/ion bombardment. It will be further apparent that, in order to effectively imprint a profile of the remaining thickness of each of the plurality of portions of the insulating layer, the stamping block may be applied by using additional pressure and/or heat.

In another example of the device and method, the mirror layers may be comprised of a metal, which is optionally an inert/unreactive metal, and/or a dielectric material. For example, the metal may be Aluminium, or silver (Ag), and may be disposed in a very thin layer (for example, under about 30 nm). In yet further examples of the method and device, one or more of the mirrors may be patterned, or pre-patterned. The patterning may comprise imparting a different nanostructure of the mirror layer, which may in turn impart a further characteristic, for example polarisation dependence, to the transmitted spectrum of light through each portion of the insulating layer.

It should be understood that any of the described aspects of the method may further comprise depositing a capping or encapsulation layer onto the second mirror layer. The capping or encapsulation layer may be added in order to impart additional mechanical and/or chemical stability into the device. Further in the interest of improving the optical properties of the device, any of the aspects of the method may further comprise (where the insulator is a polymer) heating the fabricated filter above a threshold temperature. This temperature may be the glass transition temperature of the polymer. Performing the heating may improve the smoothness of the surface of the polymer, which may advantageously increase the optical properties (e.g. the transmission efficiency) of the filter.

In another example, there is provided an optical filter device comprising: a substrate; a first mirror layer disposed on the substrate; an insulating layer having a plurality of portions, at least some of the portions having a variable thicknesses; a second mirror layer disposed on the insulating layer. The plurality of portions of the insulating layer is manufactured using the method discussed above.

### BRIEF DESCRIPTION OF PREFERRED EMBODIMENTS

These and other aspects of the invention will now be further described, by way of example only, with reference to the accompanying figures in which:

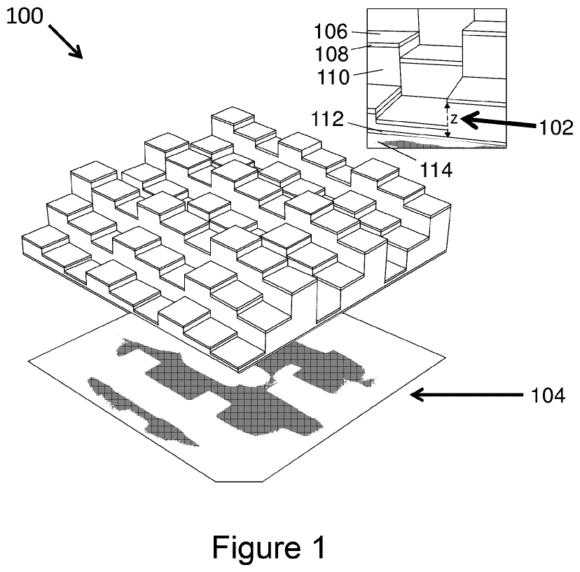

FIG. 1 shows a fabricated multi-spectrum filter, and an inset of corresponding layers;

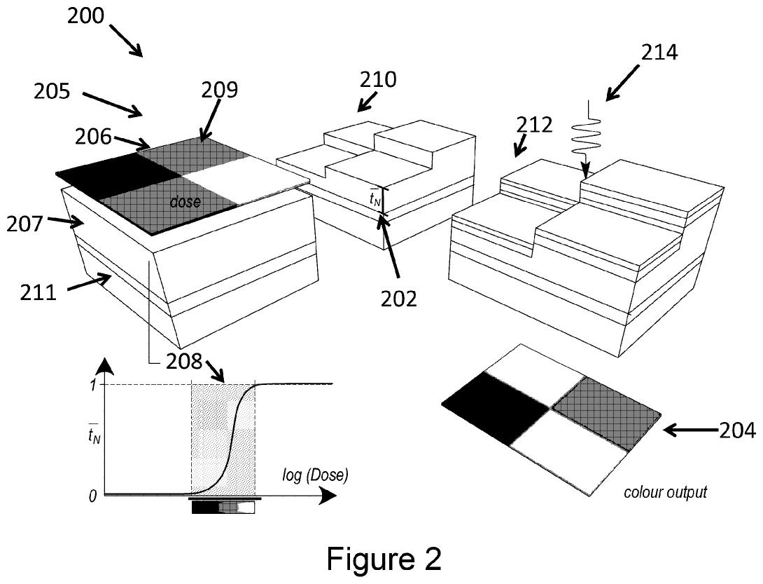

FIG. 2 shows a series of filters upon sequential fabrication steps;

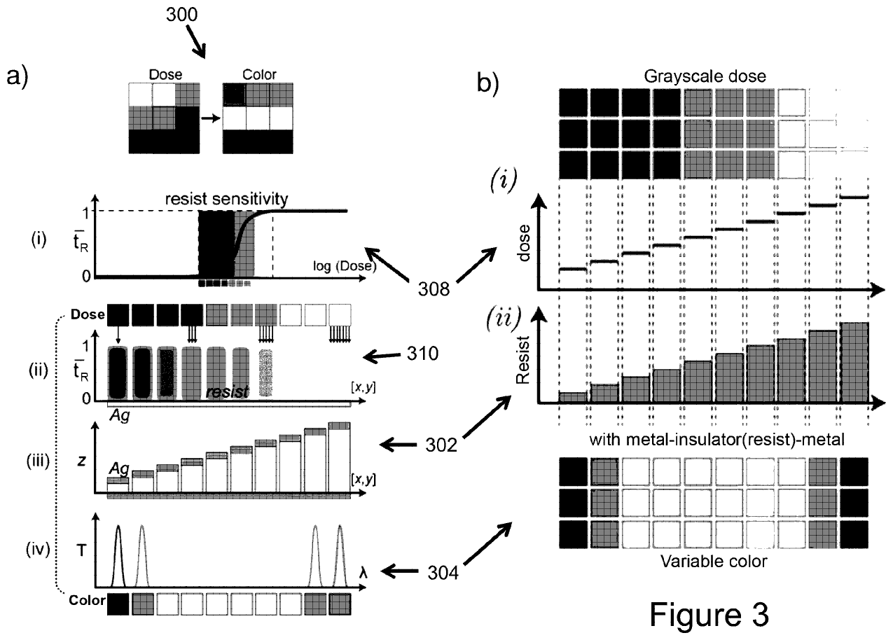

FIGS. 3a and 3b each show the correspondence between the applied energy dose, the insulator height, and the resultant colour spectrum;

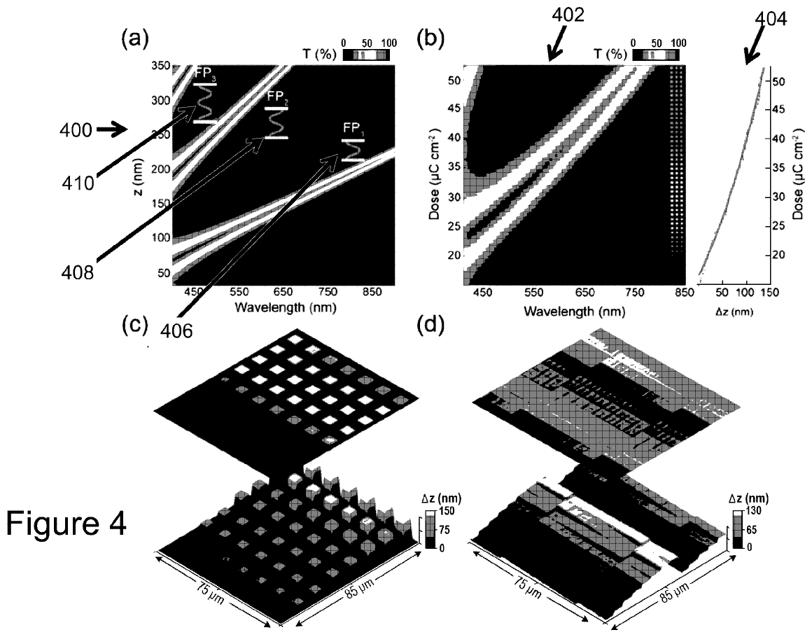

FIGS. 4a and 4b each show a graph of the wavelength transmission profiles of a range of resist thicknesses;

FIGS. 4c and 4d each show a profile of resist thicknesses correlated to a profile of transmitted colours;

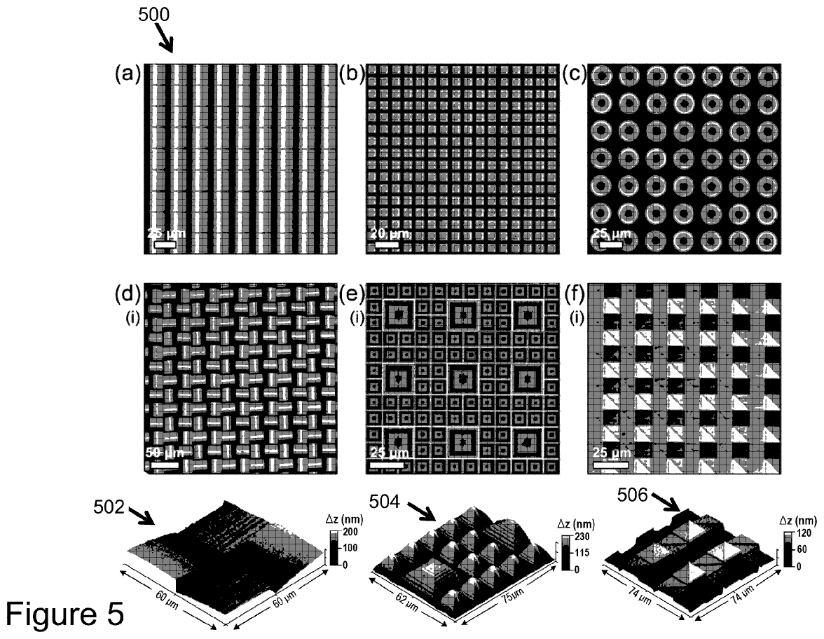

FIGS. 5a to 5f each show a mosaic of pixels produced by the three-dimensional optical filter;

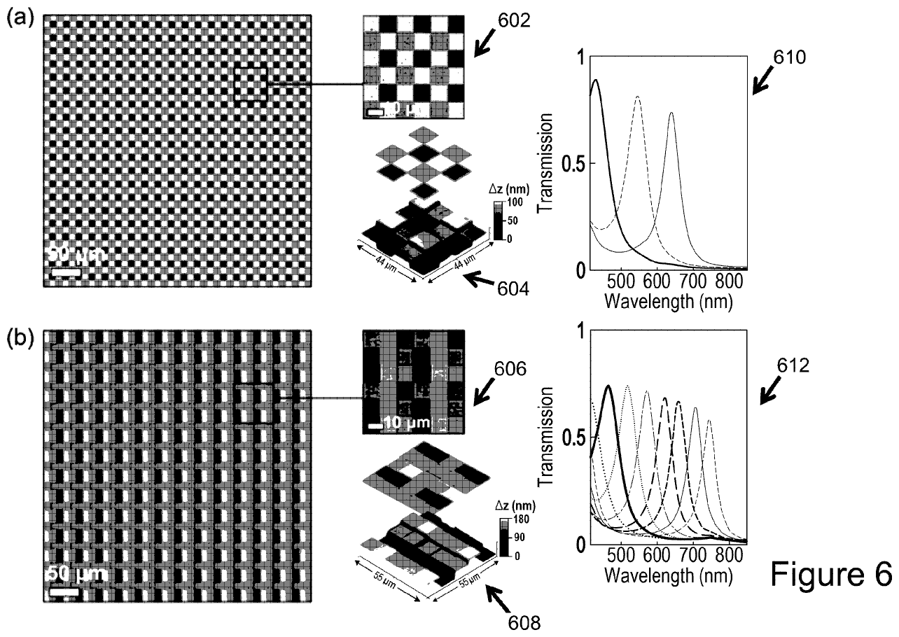

FIGS. 6a and 6b each show a mosaic of filter pixels, their corresponding resist height profiles, and their exact corresponding wavelength profiles;

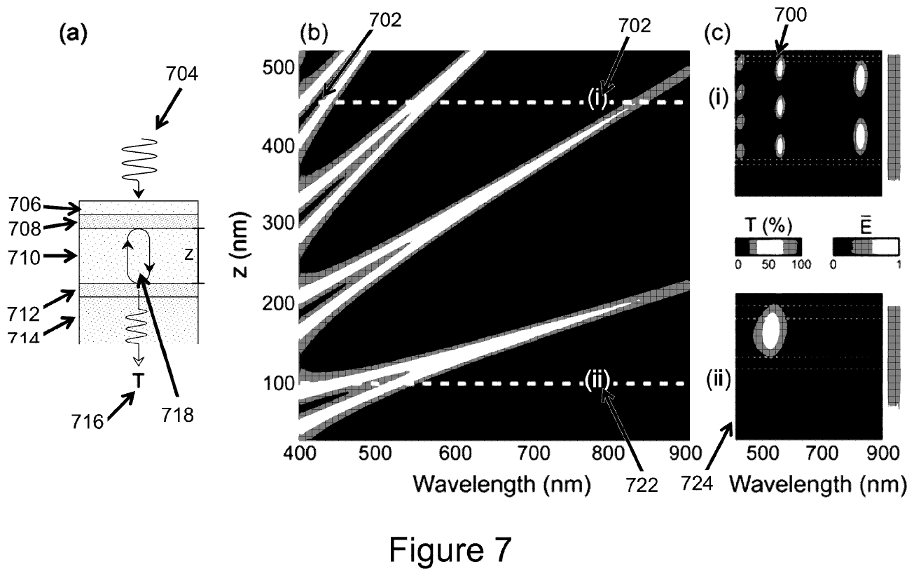

FIG. 7a shows an eigenmodes trapped within the resist layer and the correspondingly transmitted wavelength;

FIGS. 7b and 7c show, respectively, a graph of wavelength transmission profiles, and a graph of the corresponding electric fields observed within the insulator cavities;

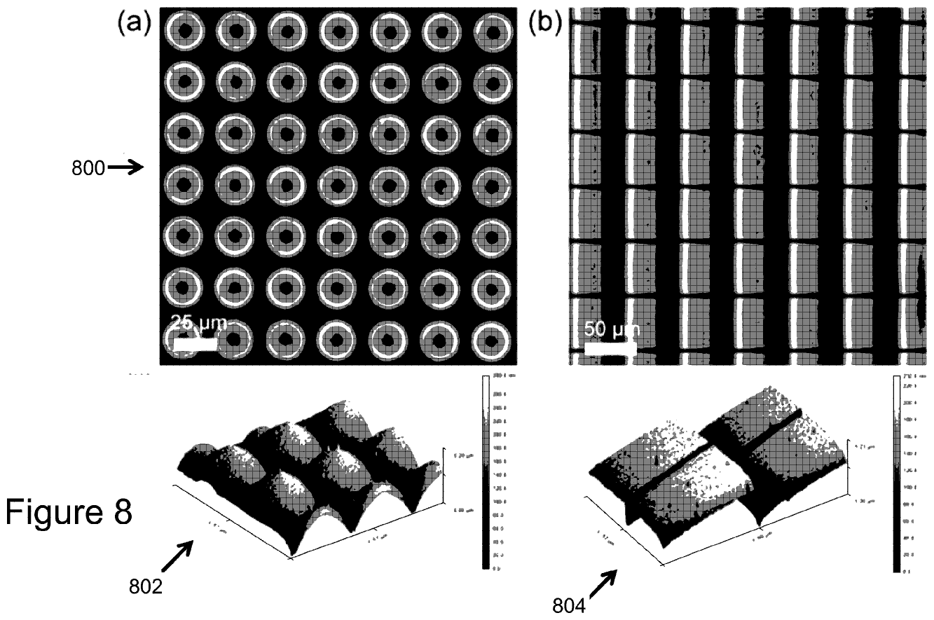

FIGS. 8a and 8b show, respectively, further examples of mosaics of filter pixels comprising domes, and linear ramps;

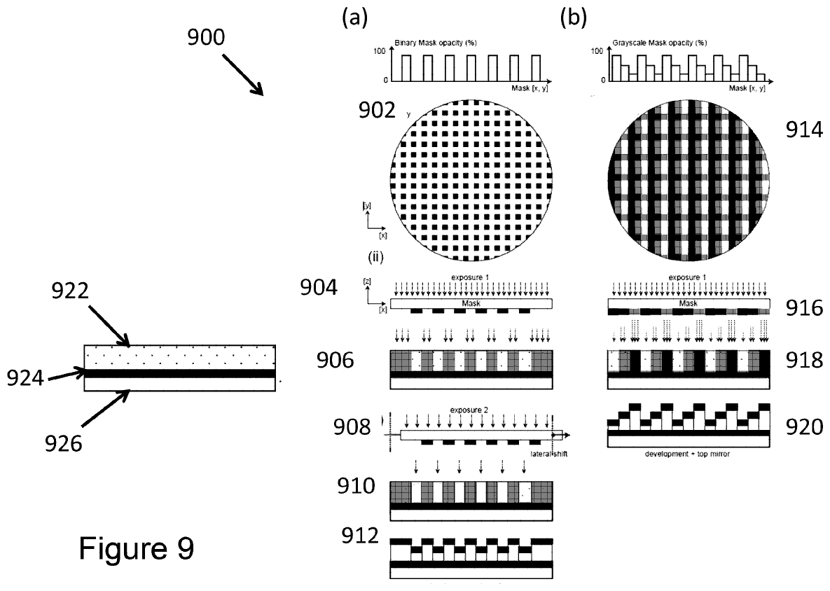

FIGS. 9a and 9b depict two variants on an alternative fabrication method comprising photomask photolithography;

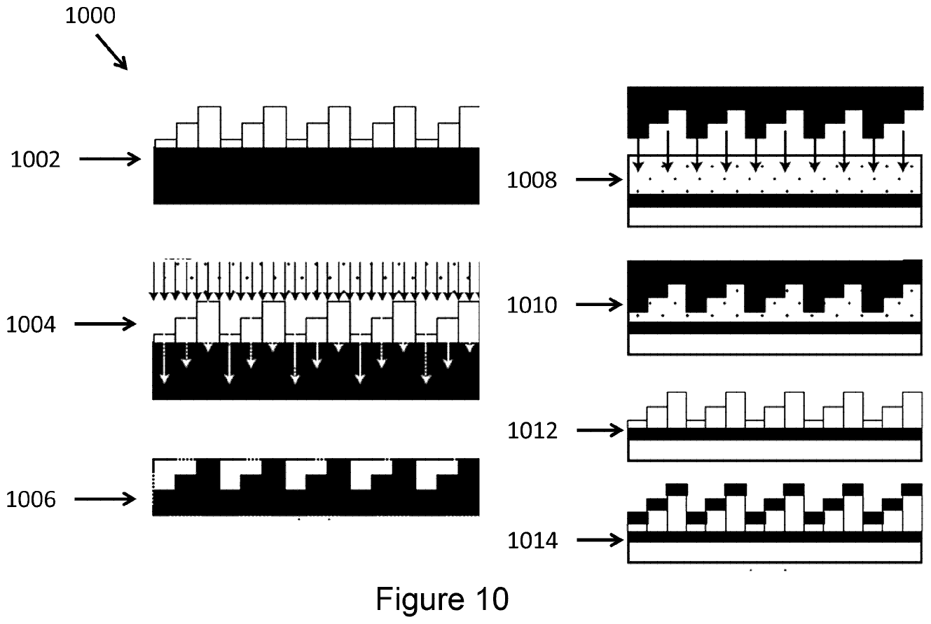

FIG. 10 depicts and alternative fabrication method comprising reactive ion etching to create a master-stamp, and an MSFA fabrication technique using the master-stamp;

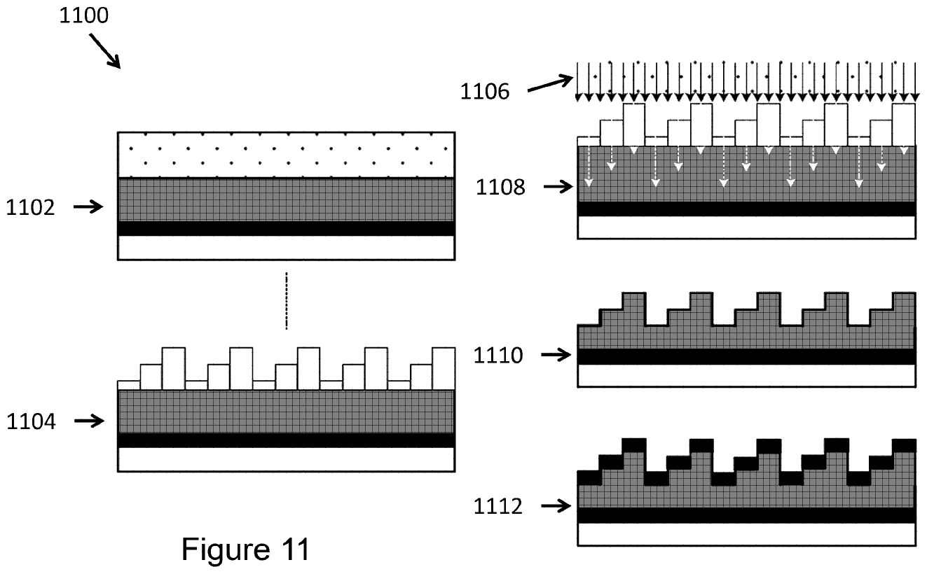

FIG. 11 depicts and alternative fabrication method comprising a single-lithographic step followed by a single reactive ion etching step of a robust insulator surface;

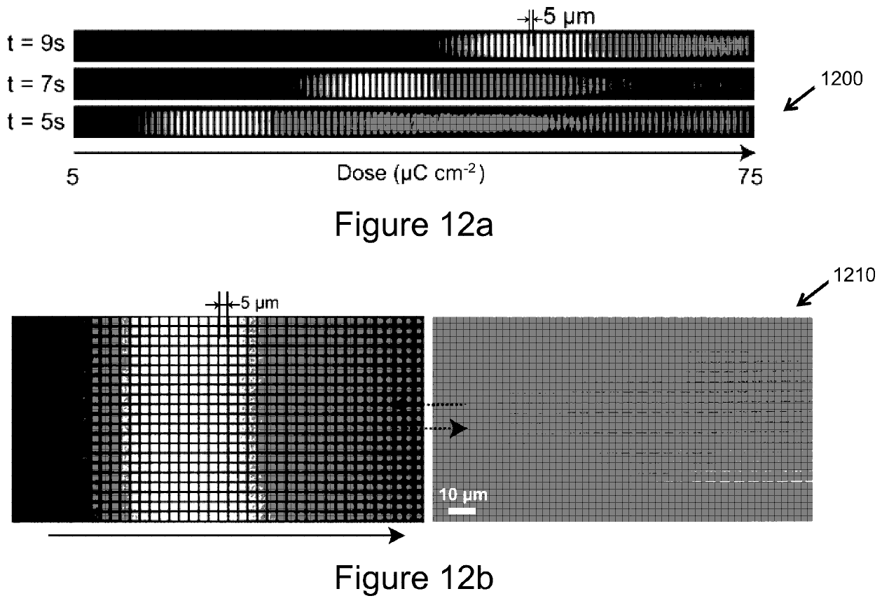

FIGS. 12a and 12b show, respectively, an illustration of effect of dose variation and development time on resultant wavelength profiles, and Optical micrograph (transmission) of an array of 5×5 μm squares (pixels) which linearly increase in exposure dose;

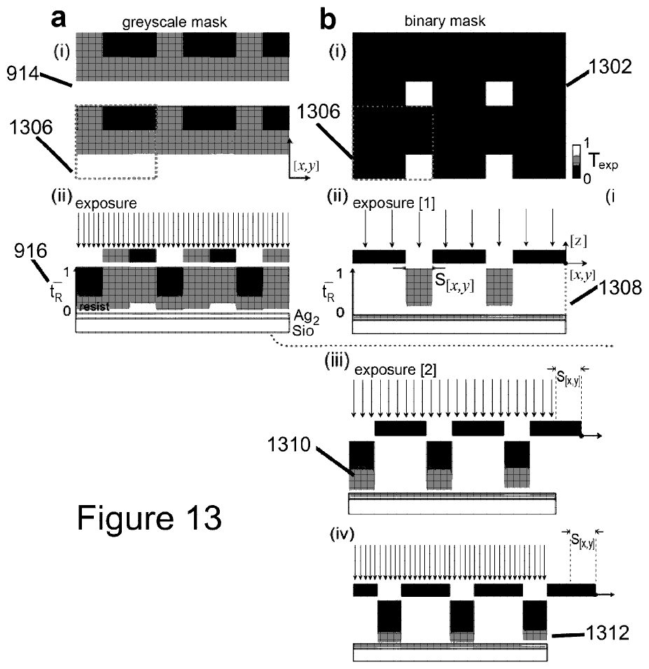

FIGS. 13a and 13b shows, respectively, fabrication process flow schematic, using a grayscale photomask, and binary photomask;

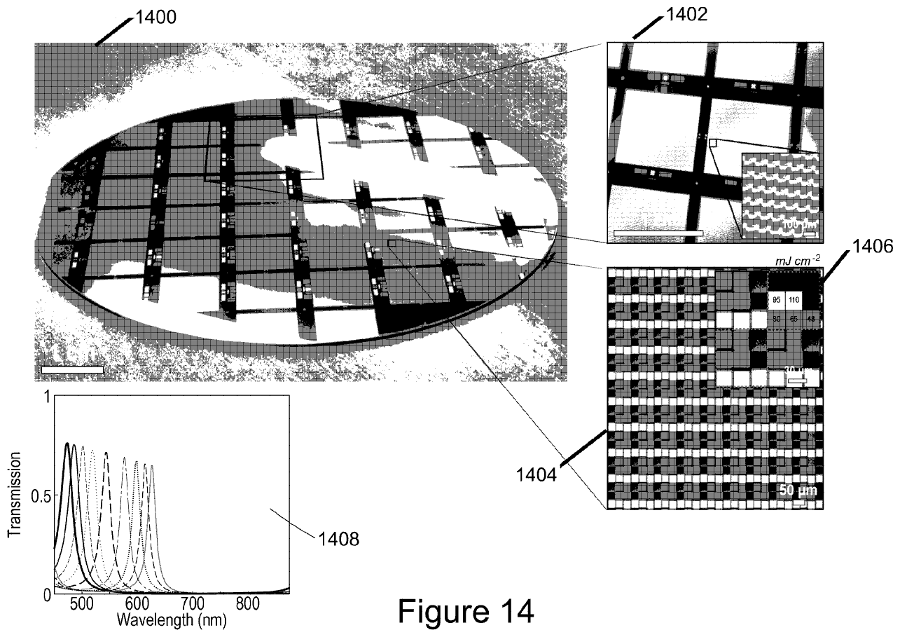

FIG. 14 shows a photograph of a 3 inch wafer with ˜32 9-band MSFAs, including a zoomed inset region, and a tiled SEM micrograph Optical micrograph (transmission) of a different region of the wafer;

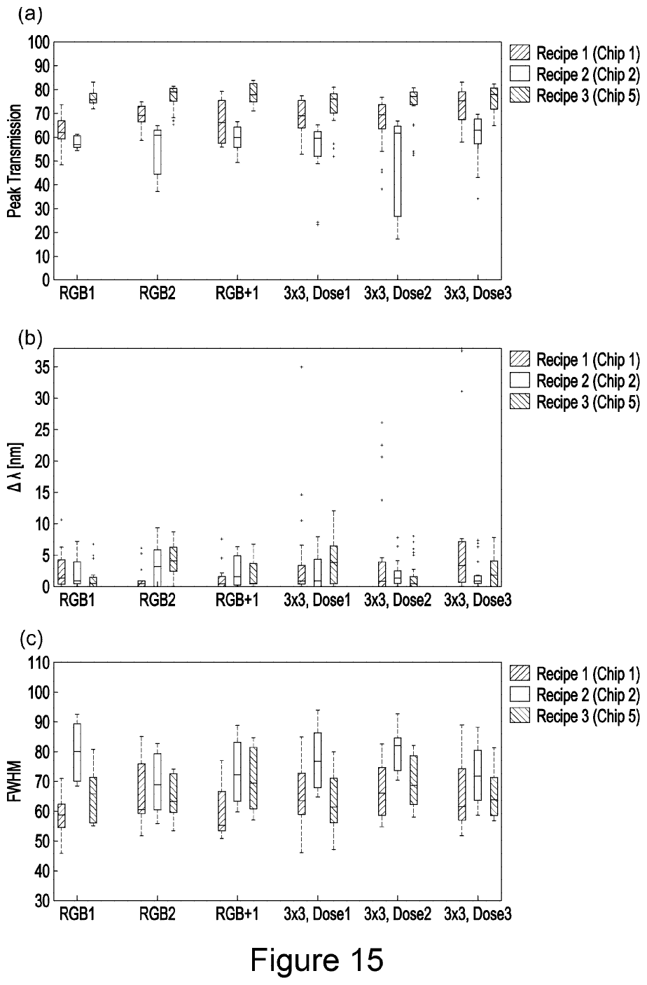

FIG. 15 shows box plots of the optical characteristics from a series of MSFA patterns from three different recipes; and

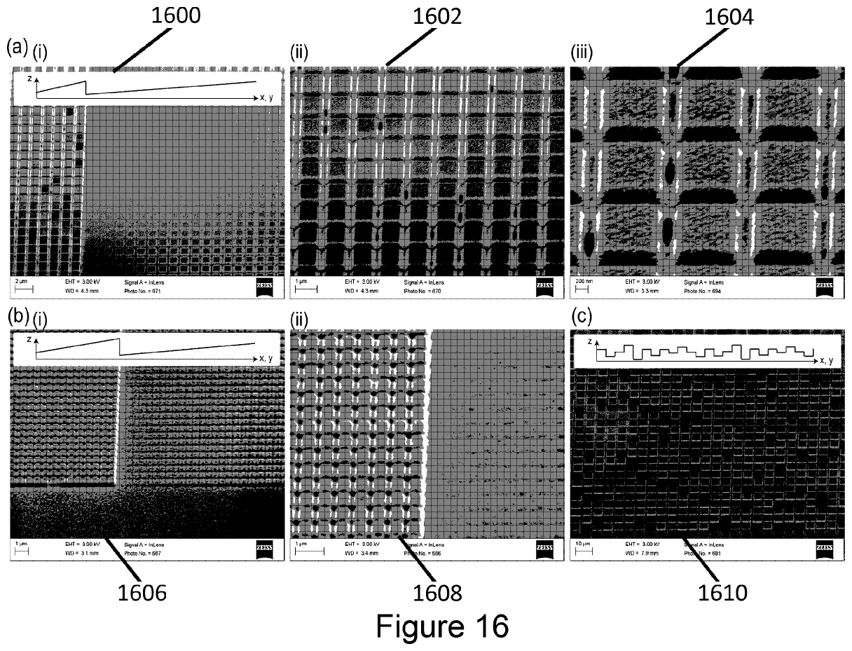

FIG. 16 shows a series of SEM micrographs of various MIM pixel arrays at several resolutions.

### DETAILED DESCRIPTION OF THE PREFERRED EMBODIMENTS

This specification describes methods of fabricating a multi-spectrum optical filter device, including grayscale and other single-step lithographic techniques, and the structure and properties of the corresponding device. Using approaches described by way of examples in the following description, it is possible to achieve multispectral imaging of several spectrally distinct target using our bespoke MIM-MSFAs fitted to a monochrome CMOS image sensor. The unique framework described provides an attractive and advantageous alternative to conventional MSFA manufacture, and metasurface-based spectral filters, by reducing both fabrication complexity and cost of these intricate optical devices, while increasing customizability.

In summary, there is presented in the following descriptive examples a unique approach for producing high efficiency, narrowband, highly customizable MSFAs operating across the visible to NIR using a single lithographic processing step (grayscale-to-color), including the possibility for wafer-level fabrication. A grayscale dose matrix is utilized to generate customizable insulator thickness profiles in MIM geometries producing optical filters spanning the UV-visible-NIR electromagnetic spectrum.

Generally referring to FIG. 1, metal-insulator-metal (MIM) structures 100 are able to provide narrow-band colour filtering (i.e., narrow full-width-half-maximums, FWHM, of transmitted light spectra), in addition to high transmission efficiency (for example, 75%) optical filters. It will be appreciated that in the MIM structure, the metal layers could act as mirrors and therefore could also be termed as mirror layers. In such MIM structures, the insulator (or resist cavity or resist or cavity) 110 thickness 102 (the optical path length in the resist cavity) defines the spectral position of the filter, and the thickness of either or both mirrors (in other words, one or more of the mirrors) defines the bandwidth of transmitted light 104. In other words, the thickness 102 of the resist/insulator 110 controls the wavelength around which the transmitted optical spectrum is centred, and where the FWHM of the transmitted spectrum depends on the thickness of either mirror or both mirrors.

Preferably, the mirror layers 108, 112 may be made of metal (which may be an inert/unreactive, or noble, metal) which is further preferably disposed as an ultrathin (under around 50 nm, for example) layer. In preferred examples, this metal will be silver, and it may be deposited using physical vapour deposition (for example, evaporation, sputtering etc.), or chemical vapour deposition. Each layer of silver will preferably be between about 20 and 30 nm in width, and ideally about 26 or 27 nm in width. However, the mirror layers may alternatively be made of optically stacked layers of dielectric material. In either scenario, the mirror layers 108, 112 will be sufficiently translucent to allow the incident light through and into the resist cavity 110, but sufficiently optically reflective in order to put in to effect the transmission of only certain wavelengths of light.

Preferably, mirror-insulator-mirror structures can be used to excite optical eigenmodes 718 (see FIG. 7(a)) within the resist cavity 110, resulting in narrowband colour filtering. In certain embodiments, the mirrors may comprise a metal layer. Therefore, the mirror layers 108, 112 should preferably be sufficiently optically reflective in order to provide a coupling, or excitation of light within the cavity 110. As such, the thickness of the cavity, or insulator, at each portion (pixel) defines a spectral position which is defined by the excitation of the particular wavelength of light within the cavity. Subsequently, spectrum of light transmitted 104 through each insulator portion corresponds to the optical wavelength of light excited within the insulator cavity. It will be appreciated that it is possible to use dichroic mirrors above and/or below the cavity 110.

FIG. 1 depicts an example of a fabricated optical filter 100, including an inset to show the individual layers of each individual insulator or cavity portion (i.e. pixel). The layers of each pixel may include, from the bottom to the top, a substrate 144, preferably glass (for example SiO₂) or an image sensor itself, an ultrathin layer of mirror (preferably silver) 112, a resist or insulator layer 110, and a second ultrathin mirror layer 108. A further layer 106 may be disposed on top of the second mirror layer, where said further layer is designed to add chemical and/or mechanical strength to the filter device. This further (capping) layer 106 may comprise, a transparent, chemically inert, mechanically rigid material, for example, an ultrathin layer of magnesium fluoride (MgF₂), preferably disposed in uniform thickness. The substrate layer may be a transparent layer. The substrate may be an image sensor itself, onto which the filter may be directly disposed and fabricated. Alternatively, the Ag mirrors may be replaced with few layer alternating index all-dielectric mirrors (e.g. TiO₂/SiO₂)⁹, hence enabling an even more robust, chemically inert, and cost effective approach.

Further advantageously, the further layer 106 acts as a capping layer which imposes a minimal, if not improved, effect on the optical properties of the filter 100. It will be understood by the skilled person, nonetheless, that not all of these layers may necessarily be present in order to achieve a fully and high efficiency operable MSFA structure. Furthermore, additional layers may exist in other alternative fabrication processes (for example methods 1000, 1100 of FIGS. 10 and 11 respectively) in making MSFA filters.

As discussed, the resultant thickness 102 of the resist in the cavity 110, after having been developed by the single-step grayscale lithography, ultimately determines the output colour profile of the filter array. FIG. 1 further depicts the profile of optical wavelengths 104 which will result from the particular three-dimensional profile of thicknesses in the filter 100. The first mirror layer 112 is optionally disposed onto the substrate 114, for example in a uniform thickness. This uniform thickness may be varied to tune the spectrum selectivity (FWHM) during the fabrication process. Although the final filter is likely to comprise various different thicknesses of resist or insulator, corresponding to various different coloured pixels, the second mirror layer 108 disposed onto each of the resist portions (pixels) is generally of an equal/uniform thickness throughout the device. Specifically, the uniform thickness of this second mirror layer 108 may be up to around 50 nm, and in a preferable example may be around 26 or 27 nm. In one example, this range is applicable to metallic mirrors.

The present disclosure teaches of an improvement to the known fabrication techniques of MIM structures and MSFA devices in general. This improvement comprises, in part, a grayscale lithography process. Grayscale lithography is a single-step lithographic process in which in-plane spatially variant three-dimensional information can be imparted into a photoresist through a variable energy exposure. The exposure controls the local solubility of the resist and therefore, during resist development, the remaining resist thickness depends on the total energy delivered to the volume of the resist. By determining resist sensitivity (remaining resist thickness vs. dose) a particular grayscale energy dose pattern results in a particular 3D resist profile. Advantageously, this single-step lithographic process allows fabrication of particular 3D resist profiles, which are highly versatile and readily customisable.

FIG. 2 depicts the stages of fabrication 200 of a multi-spectrum filter 100 (of FIG. 1) using the grayscale lithography procedure. In a first step 205, the structure 206 preceding the exposure to the energy beam comprises a resist layer 207 which is initially of uniform thickness. The overlaid grayscale pixels 209 on the structure 206 represent the dose exposed to each portion of the insulator surface; white corresponds to a high dose and black corresponds to a low dose. In this example comprising a negative-tone, therefore, a high energy dose corresponds to a resultant thicker resist pixel layer thickness 202 (see the second step 210). The exposed filter is then developed in order to remove portions of the exposed resist. In one example, this development will involve exposing the resist to a chemical etching/developer solution. The chemical developer solution dissolves the surface of the resist to varying extents, depending on the variable solubility of the resist after having been exposed to the grayscale electron beam. The development process may also involve a further washing with de-ionized water. For example, the chemical developer solution may comprise full concentration AZ-726-MIF developer solution, which preferably may be used in conjunction with the negative tone MaN-2400 resist. It will be understood, however, that the type of chemical developer solution used is generally chosen dependent on the resist material being used. As will be discussed, it is possible to use a positive-tone resist as well.

The filter resulting from the exposure in structure 206 (in the second manufacturing step 210), and the subsequent development, possesses multiple remaining resist thickness 202, defining pixels, where the pixels are directly adjacent to one another. At a third step 212, the second mirror layer (as in 108 of FIG. 1) and capping layer (106 of FIG. 1) are disposed on top of the remaining insulator portions 202. Subsequently, an incident source of light 214 will be filtered differently according to the thicknesses 202 of each of the resist pixels. The result is a transmitted colour profile 204 of specific optical wavelengths, where each pixel transmits optical wavelengths of a different spectral position.

It will be understood by the skilled person that in this example, a negative-tone resist is being used which strengthens upon exposure to the dose of energy. In another example, a positive-tone resist may be used which weakens upon exposure to an dose of energy. In this another example, a high (white) energy dose would result in a thin resist thickness 202. For the negative-tone resist, FIG. 2 shows a resist-sensitivity profile 208. It can be seen that a certain range exists wherein an increasing dose of energy corresponds directly to an increased thickness of remaining resist (after the development and/or washing procedure). It will be understood by the skilled person that any energy greater than the lower bound of this range (marked by vertical dashed lines in 208), represents a chemically activating dose of energy. In other words, the range represents an energy dose capable of strengthening, weakening, or etching the insulator material. It will also readily be understood that this range is a property of the particular resist material used. For example, the resist material will be sufficiently energy-sensitive such that a chemically activating dose of energy may be as low as approximately 15 μC cm⁻² It will be readily understood that the value of energy dose is resist dependent, however. Furthermore, when the energy beam comprises a beam of photons, the respective unit of energy/power may be mW cm⁻².

A further post-fabrication step may be used after having constructed the MIM structure. The completed device, which may be an MSFA or CFA filter for example, can be heated or baked past the glass transition temperature of the resist/insulator. Performing this bake softens the resist, which may create a smoother surface. This smoother surface persists once the device is cooled after having been baked. The smoother surface may subsequently improve the optical performance characteristics of the filter, for example, by increasing the overall transmission efficiency through the layers. This technique, called resist thermal reflow, is described in more detail in later passages.

The advantages of applying the grayscale lithography to produce the MIM structure are highlighted in this disclosure. In particular, it is possible to produce highly efficient MIM CFAs, which may be disposed on any suitable substrate including glass or directly onto image sensors. Therefore, such CFA (or MSFA) filters may be used to image multi-spectral test scenes when used in combination with a conventional CMOS image sensor. The resist thickness produced as a result of the grayscale lithography, which is used as the insulator (cavity) material, is determined by exposure energy. It will be appreciated that this is applicable to the filters atop of any electronic image sensor (CCD-based, CMOS-based, sCMOS-based) either fabricated directly on top of or bonded to. It will be understood that ‘multi-spectral test scenes’ are for imaging in general with an intention of spectrally discriminating the scene's information i.e. from a conventional RGB based filter array/sensor, up to any kind of multispectral array. For example, the end applications could be diverse, e.g. imaging biological tissue, imaging chemical mixtures, and many others as applicable.

FIGS. 3a and 3b both illustrate the concept of variable energy dose exposure. Ultrathin (for example, about 26 nm thick) silver mirrors enclose the spatially varying and thickness varying (<200 nm) insulator (resist). Highly efficient (about 75%) and narrow linewidth (a FWHM of about 50 nm) colour filtering from the ultra violet visible near infrared (UV-VIS-NIR) spectrum range may be achieved. The technique of grayscale lithography in fabricating MIM structures to generate CFAs and MSFAs exhibits multiple advantages over the state of the art, in terms of fabrication versatility, cost, fabrication efficiency, and in terms of the filter device properties itself. Advantageously, a high current may be used by the electron beam lithography which, in combination with relatively low critical exposure dose of the resist, allows for fabrication over relatively large sample areas (for example, several mm²) in reasonably short time periods.

Grayscale electron beam lithography (G-EBL) may be used to spatially vary the insulator (or resist) layer, where the insulator is disposed onto a substrate 211 (see FIG. 2). Optionally, the substrate will be made of glass, and preferably comprises SiO₂. In examples, the substrate may comprise an image sensor itself. The result is a spatially variant transmission filters operating across the visible and near-infrared part of the electromagnetic spectrum. A further advantage of the combination of material layers described in this disclosure, used for fabrication of MSFAs using G-EBL, is that it is possible to achieve, dependent on the choice of material and geometries of the device, about 75% transmission efficiency and about 50 nm linewidths (FWHM). In other words, a narrow spectrum of transmitted light may be achieved through each MIM filter portion, which corresponds to a highly selective MFSA or CFA.

G-EBL is a technique capable of generating three-dimensional (3D) resist profiles through dose-modulated exposure schemes. For example, in FIG. 3, the molecular weight of the resist (polymer) is modified 310 through the dose 308 of energy exposed to the resist. Thus, the selectivity of developer (rate of development) is a function of the energy dose. For a grayscale profile, the remaining resist thickness 302 (post-development) depends on the dose 308 and/or development time. By utilizing the 3D profile resist as the insulator material in a MIM optical filter system, spatially dependent 3D MIM structures can be produced which exhibit transmission of a multi-spectrum of optical wavelengths 304. Therefore, highly efficient CFAs or MSFAs can be fabricated.

In one example, the material of the insulator may be a negative-tone e-beam resist material such as ma-N 2400 series. This resist material possesses a high resolution capability for use in G-EBL, which effectively allows for increasingly small and precise pixels in the mosaic. Further advantageously, the resist possesses a relatively high sensitivity. It will be understood by the skilled person that a ‘Negative’ resist has the property that it is chemically strengthened upon exposure to a chemically activating dose of energy, such as an electron beam of sufficient intensity. Specifically, the internal chains of the polymer material become cross-linked upon exposure to energy, which makes it more resilient to removal. As such, a variable dose of energy may be exposed to very specific portions of the resist material in order to generate a complex profile of resist heights. Following exposure by the variable doses of energy beam to a plurality of portions of the resist surface, the portions of resist material which have not been sufficiently strengthened by the beam may be removed/dissolved by some development process; for example, dissolved or washed away using a chemical solvent (or any suitable chemical development solution), optionally followed by a further wash with deionized water.

The amount of resist material subsequently remaining corresponds (proportionally, in the case of negative-tone resist) to the dose of energy received at each portion. This correspondence is sometimes called the resist sensitivity, and a remaining resist thickness vs dose profile 308 (or contrast curve) may be predetermined prior to fabrication for each resist material (see FIG. 3). In other words, the molecular weight (and correspondingly, the resultant thickness after development) of the resist is modified through exposure dose, thus making the rate of development a function of dose.

It is possible to use the spatially variant CFAs, or MSFAs, in combination with monochrome CMOS (complementary metal-oxide semiconductor) images sensors, for multi-spectral imaging of a variety of spectrally distinct targets. MIM structures for optical filters bear the advantage that they possess highly efficient filtering characteristics. In other words, they allow multi-spectrum and selective narrow-band filtering of light, whilst allowing a majority of the desired wavelength of incident light to be transmitted. MIM structures also exhibit reduced angular dependency; the described methodologies allow MIM-based MSFAs of less than around 200 nm, resulting in reduced angular dependencies that typical multilayer alternating index fingers. Both of these features make MIM structures good candidates for CFAs and MFSAs. Further alternative uses for such MSFA filters exist for example, the direct illumination of a target to be imaged.

As described, the transmitted wavelength of light is indicative of the thickness of the resist cavity. In between the two mirror layers, the light is reflected such that an eigenmode is excited by a self-interacting wavelength of light being internally reflected between the mirror layers. Subsequently, only this excited wavelength of light, or light of a very similar wavelength, is allowed to pass though the filter. That is, only light centred about a particular spectral position, defined by the self-interacting wavelength, will be transmitted through the filter.

In more detail, the ultrathin mirror layers (which in may be metallic) are preferably partially reflective dispersive mirrors which allow the coupling of energy between the top-and-bottom mirrors. When the mirrors are separated by an insulator, creating a finite optical path length between the two, eigenmodes (harmonic resonances) are excited which correspond to the electric field of incident light tunnelling through the top-mirror layer and becoming highly concentrated in the central region of the insulator cavity. Due to the insulator thickness, transmission filtering at the system eigenmode wavelength occurs. In other words, the insulator thickness corresponds to the spectral position of the transmission peak.

Furthermore, the mirror thicknesses control the coupling efficiency into the system, and affect the transmission linewidth (the transmission FWHM). Hence, depositing a thicker mirror (either or both of the first and second mirror) results in a more selective and narrow spectrum of transmitted light (i.e., a narrower FWHM). However, the thicker mirror may conversely affect the overall transmission, and as a result the overall transmission of the narrower transmitted spectrum may be lower.

FIG. 4 demonstrates an operating principle of the optical filter; the generation of colour from grayscale dose modulation 400. FIG. 4a shows an electromagnetic simulation of the transmission response of a continuous silver-resist-silver (Ag-resist-Ag) MIM cavity with a nondispersive insulator (or resist, where the refractive index was simulated as n=1.653) separating the Ag mirrors. As the insulator thickness (denoted as z) increases, the optical path length increases between the mirror layers increases. Consequently, the spectral position of the eigenmode red-shifts accordingly. That is, the wavelength of transmitted light increases. Moreover, multiple transmission peaks are excited for thicker insulator layers, corresponding to the additional higher order 410 harmonic modes (Fabry-Perot-like modes) of the system. For the specific simulation used in creating FIG. 4a, the geometries and compositions of the layers are as follows, beginning at the bottom layer: SiO₂ substrate—Ag first mirror (26 nm)—resist (n=1.653)—Ag second mirror (26 nm)—MgF₂ Capping layer (10 nm). It will be appreciated that the disclosure is not limited to Fabry-Perot-like modes. Other modes such as guided (wave-guided) modes, plasmonic (e.g. surface plasmon) and magnetic resonances (e.g. dielectric resonance) could be equally applicable.

FIGS. 4a and 4b further shows that the resultant transmission modes for each square (that is, each insulator portion exposed to a variable dose of energy) spectrally shifts from optical wavelengths of 400 to 750 nm as the exposure dose increases. In turn, these greater optical wavelengths correspond to thicker insulator layers. As seen in FIG. 4a, only the first-order resonance 406 is present at in the smaller insulator layers, developed under smaller energy doses. For increasingly higher doses, the second-order resonance 408 mode is also excited. Increasing development time further, for constant dose range, results in blue-shifting the optical transmission, and even a third order resonance 410 mode is predicted. Transmission of up to about 75% and narrow FHWMs of about 50 nm are observed in (b)(ii), with thickness values up to about 150 nm.

FIG. 4b shows the experimental optical transmission spectra 402 for dose modulated (where the electron beam energy dose used was 15-55 μC cm⁻²) 10 μm rectangular patterns MIM structure, with a final thickness obtained using an atomic force microscope (AFM) in 404. To achieve this, a 2D array of 10 μm squares (x-y dimensions) is assigned increasingly higher dose values, such that after G-EBL (for a constant development time) each square has varying, 3D, final thickness in the z-dimension. Specifically, the experimental spectra 402 has been produced using ma-N-2405 resist developed under the electron beam for 10 s, with two 26 nm Ag layers and 12 nm layer of MgF₂ encapsulation layer. Nevertheless, it should be understood that different combinations of resist, mirror layers, and capping layers can achieve very similar results. For example, SiO₂ may also be used as an encapsulation/capping layer. FIGS. 4c and 4d each show two experimental dose modulated patterns of MIM structures: the upper image shows a 2D colour profile measured experimentally from an optical microscope, and the lower shows the corresponding structures measured from an atomic force microscope (AFM). It can clearly be seen in FIGS. 4c and 4d that the resultant cavity height variation, generated from a linearly variable grayscale exposure dose, results in varying colours in transmission.

FIGS. 5a to 5f each demonstrate the versatility of this approach, where each respective subfigure possesses a different mosaic pixel design shown under the optical microscope (transmission). Further, atomic force microscope (AFM) images 502, 504, 506 are given, which correspond respectively to FIGS. 5d, 5e, and 5f. To achieve this design variety using conventional techniques would be extremely process intensive, especially to achieve the high optical performance shown. Using conventional techniques in the art would require many lithographic steps, materials and masks, and would thus be prohibitively expensive and/or time consuming. Advantageously, methods described in this specification allow the versatile mosaic patterns shown in FIG. 5 to be fabricated using only a single lithographic step. Minimal cost, time, and consumable materials are used in the fabrication process of this specification. Moreover, all patterns may be fabricated onto the same glass chip (for example, SiO₂ substrate).

FIGS. 6a and 6b show, respectively, two embodiments of colour filter arrays produced using the single step G-EBL fabrication method. The arraignments of both FIGS. 6a and 6b use the same pixel density. FIG. 6a shows a typical CFA filter which takes the form of a Bayer filter 602, whose pixel pattern is well-known. The Bayer filter includes 2×2 array units each comprising two green squares on one diagonal, and a single red and blue square on the remaining squares. The profile of thicknesses 604 produced by the G-EBL which corresponds to this CFA is also shown as an underlay image, which is a topography profile obtained from an AFM image. Further, the exact optical spectrum produced 610 by the filter as a whole is given.

FIG. 6b shows a more sophisticated MSFA 606 with nine distinct optical transmission wavelengths according a 3×3 unit array. The profile of thicknesses 608 produced by the G-EBL which corresponds to this MSFA is also shown as an underlay image, where nine distinct resist thicknesses can be seen. Again, the optical spectrum produced 612 by light transmitted through the filter as a whole is given. The G-EBL technique possesses the advantage beyond a standard Bayer filter that high transmissions can be achieved. The spectra 610, 612 corresponding respectively to the G-EBL Bayer filter and MSFA filter, show these high optical transmissions (y-axis) for all colours/optical wavelengths.

FIG. 7a depicts the optical coupling 718 and production of the eigenmode inside the insulator cavity 710. As a result of the excitation 718 between the two mirrors 708, 712, the incident light 704 (containing a full spectrum of optical wavelengths across the visible spectrum) becomes filtered so that the transmitted light 716 comprises only a particular spectrum of wavelengths corresponding to the resist thickness. The filter structure further shows the capping layer 706 and the glass substrate 714.

FIG. 7b shows a further finite difference time domain (FDTD) simulations of a MIM cavity with silver (Ag) mirrors. The transmission as a function of insulator (resist) thickness is shown, whereby it can again be observed that thicker resist layers result in multiple higher-order excitations 720 (at shorter wavelengths, for example 702) in addition to the red-shifted, longer wavelength, first-order excitation mode. As in FIG. 4a, wavelength (x axis) is plotted as a function of resist thickness in nm (y-axis).

FIG. 7c shows graphs of the corresponding electric fields 700 (or E-field) observed within the insulator 710 cavities. The E-field shows highly concentration regions within the resist cavity which corresponds exactly to the harmonic resonances of the eigenmodes. Due to the larger cavity thickness, multiple transmission peaks occur within a single insulator portion. The higher-order excitations 702 (eigenmodes) which become excited in the thicker insulator cavities can be seen to produce corresponding higher order E-field intensity profiles 700. Similarly, the first-order 722 excitation present in the thinner resist cavities can be observed as only a single E-field intensity 724 in the corresponding E-field observations. The geometry of the filter used in the simulation E-field observations is as follows: SiO₂ (bulk) 714—Ag (25 nm) 712—Resist (n=1.653) 710—Ag (25 nm) 708—MgF₂ (10 nm) 706.

FIGS. 8a and 8b each further exemplify the high versatility of the G-EBL technique in producing optical filters. In contrast to the previous examples which show mosaics of pixels which have discrete, stepwise height changes between individual pixels, these figures exhibit resists with continuous surface profiles. That is, individual pixels corresponding to a single transmission colour cannot be so easily defined.

FIG. 8a shows a mosaic 800 of circular pixels, where the individual colour bands form concentric circles in place of tessellating squares or triangles. It can be seen that these concentric circles correspond to an insulator surface profile of multiple domes. At the greatest height of the domes, the filter only transmits the longer-wavelength red/NIR light. Following the smooth gradation down the slope of the dome, it can be seen that increasingly blue-shifted wavelengths are transmitted through the portions of the optical filter. FIG. 8b shows a mosaic of apparently tessellating rectangular pixels. However, it can be seen that the corresponding resist profile 804 corresponds again to a smooth gradation of insulator height which forms a linear ramp.

FIGS. 9a and 9b each depict variations of an alternative embodiment of the fabrication method which may be used to produce CFA and MSFA three-dimensional multi-spectrum optical filters. However, this alternative example uses a grayscale (see FIG. 9b) or binary (see FIG. 9a, or FIG. 13; mask 1302) photolithography (PL) mask filter which is placed in between a uniformly applied energy beam, and the photoresist layer (precursor to the filter) to be exposed. The mask, or precursor filter, is applicable to being used in the methods described in both FIGS. 9a and 9b, and as before may be used to create a filter comprising a glass substrate 926, a bottom mirror layer 924, and the resist 922. In FIG. 9, the resist is a negative-tone resist. Generally, this photolithographic technique involves applying a dose of energy in the form a photons. The energy density of the photon beam is thus attenuated by portion of the mask, e.g, depending on a chromium content in different portions of the mask. Alternatively, an electron beam may also be used in conjunction with a mask.

Generally, the mask may define an attenuation profile. When the mask is placed in front of a resist material being used to fabricate an MSFA filter and exposed to a dose of energy such as a beam of photons, or a lamp, the mask attenuates the energy dose according to its attenuation profile. Thus, the attenuation profile of a mask may be transferred onto the resist. After a development step to remove portions/volumes of the resist material, the resultant thickness of the resist is representative of the attenuation profile of the mask. Therefore, it will be understood that this method may be a single-step lithographic process (e.g. in 9b).

The method described by 9a comprises laterally translating the PL mask, which has binary opacities, in order to impart a grayscale photoresist pattern onto the resist precursor. A PL mask with binary opacity values 902, where individual pixels arranged in a 2D array is shown in plan view. In step 904, the areas in the mask 902 which are most opaque (black) at least partially block the light, and the white (transparent) areas allow the light to substantially pass through the mask. The same mask may be laterally shifted in order to expose a greater area of the resist precursor. The magnitude of light which reaches the surface of the precursor, through the PL mask, can be seen in step 906. In step 908 a second exposure may be performed, which may be a different exposure to the one performed in step 904. This step 908 may be repeated for arbitrary designs an arbitrary number of times, whereby each exposure (seen again in step 910) may yield a different final resist thickness. Thus, on the schematic of FIG. 9a there are two alternating parts of the resultant resist 912 which correspond to different exposure doses. The final filter result in 912 can also be seen to have a top mirror deposited onto the resist surface. As described in this disclosure, the top mirror 922 is deposited which creates a cavity (metal-insulator-metal geometry or otherwise) and spatially variant optical filters are subsequently produced.

FIG. 9b describes a method in which a grayscale PL mask 914 is used which has a spatially variant grayscale intensity opacity profile. As such, multiple portions exist on the mask, where the mask possesses more than 2 distinct opacity values. This grayscale PL mask can be used to impart a grayscale thickness profile into a photoresist. As with FIG. 9a, using a uniform exposure of energy/light (a single flood exposure), the light is attenuated to varying degrees due to the grayscale opacity profile of the mask. In order to achieve the variable levels of opacity within the mask, in a preferred example, alternating thicknesses of layers comprising chromium may be used. Alternatively, any other material or structure may be used, which is able to suitably attenuate the light to varying degrees. The different intensities of grey in 914 correspond to different levels of opacity (attenuation of the light). Step 916 depicts exposure of the mask, which overlies the photoresist precursor. The opacity in each area in 914 defines the extent of attenuation the light, and so also defines the imparted dose profile and the resulting resist thickness. In other words, more transmissive (white) regions in 914 allow more light through the mask, which consequently results in a thicker final resist portion exhibiting a red-shifted (longer wavelength) spectral response. In more detail, after the light is attenuated, varying degrees of light intensity can be seen to reach the precursor in 918, whereby the polymer is strengthened to a varying degree according the exposure. The final filter result in 920 can also be seen to have a top mirror deposited onto the resist surface.

The method described in FIGS. 9a and 9b uses a negative-tone photoresist material 922. However, it will be readily understood by the skilled person that a positive-tone photoresist may alternatively be used. The only difference to the method in using a positive tone resist would be that the thickness profile would be inverted when used under the same exposure conditions. It will be understood that the fabrication method of FIGS. 9a and 9b is also a single step lithographic process like the electron beam grayscale lithographic process discussed in other examples. The only difference is that instead of varying the intensity of exposure by the light source of the grayscale lithography, the process of FIGS. 9a and 9b uses a separate mask having portions of different levels of opacity to control the intensity of a uniformly applied beam through the mask.

FIG. 10 describes a further alternative example of a method which may be used to produce CFA and MSFA three-dimensional multi-spectrum optical filters. This method 1000 first fabricates a robust ‘master’ stamp, or dye, which may then be used to increase the throughput of the device fabrication, as the stamp may be used in a single step to produce a complex profile of resist thicknesses which again define a three-dimensional optical filter. Advantageously, this method 100 facilitates mass-production of optical filters according the master-stamp. It will be understood by the skilled person that this method may produce a three-dimensional optical filter which is exactly analogous to an optical filter which may be produced by the described G-EBL technique 200, and the grayscale PL mask method 900.

The method of producing a master stamp comprises pre-fabricating 1002 (according to one of the previously described G-EBL methods 200) a grayscale resist on top of some robust/resilient material which will form the master stamp. The robust material may comprise silicon, and may be quartz. An etching step 1004 may then be performed to etch portions of the robust master-stamp precursor, to varying depths. Reactive-ion etching (RIE), which is a dry etching technique, may be used to etch the stamp material to impart the resist grayscale profile into the master stamp material. In some examples, heavy ions, such as Ar⁺, may be used in the RIE. The heavy ions are bombarded into the master-stamp material via the overlying grayscale resist. Alternatively, a wet etching technique with a chemical bath, comprising chemicals such as hydrofluoric acid, can be used. A thicker resist area will more substantially attenuate the intensity of the reactive ion species which reaches the robust stamp material. As such, due to the profile of thicknesses in the resist material, a corresponding grayscale resist pattern is imparted into the master stamp material. The resultant master stamp is seen in step 1006.

Step 1008 depicts inverting the stamp and bringing it into contact with another polymer (for example, a heat-sensitive photoresist or other suitable polymer), which is disposed on top of a bottom mirror and a glass substrate. Step 1010 depicts the imprinting or moulding step, comprising stamping into the polymer. It is further possible to incorporate additional pressure and/or heat over a variable amount of time when imprinting the master stamp to the photoresist. The resultant grayscale pattern is imparted into the resist in step 1012, and, after the removal of the master stamp, the top mirror layer is deposited onto the resist surface in step 1014.

FIG. 11 describes yet another alternative example method 1100, which generally comprises using a combination of the described G-EBL on a photoresist/insulator and RIE on a more robust insulator material. The result of the process described by FIG. 11 is an MSFA optical filter, which again possesses the MIM structure, but which is more resilient and robust than the filter produced the G-EBL/PL mask techniques (as in 200 and 900) alone. Advantageously, the filter produced by this method is likely to have an increased longevity (e.g., chemical stability, mechanical stability and increased optical performance due to semi-crystalline nature).

The precursor 1102 in the robust MSFA fabrication method 1100 comprises one additional layer, which is a more robust insulator. This more robust insulator is deposited between the bottom mirror layer (e.g. 924) and the previously-described photo-resist layer (e.g. 922).

With a grayscale resist profile atop of this structure, an etching step (RIE or otherwise) can be performed to impart the grayscale profile into this insulator. Preferably, the more robust insulator layer is a substantially transparent material, and may comprise silicon (for example quartz (SiO₂) in its crystalline form). A photolithographic technique (G-EBL 200 or mask photolithography 900) is then performed on the upper resist layer to produce a structure 1104 with a 3D resist thickness profile. Method step 1108 depicts the RIE method in which the robust insulator material is anisotropically etched. In other words, the extent of etching into the various portions of the robust layer is determined by the overlying photo-resist thickness. The intensity of the reactive ion bombardment 1106 is uniform across the entire region of the filter, wherein ions in the ion bombardment may comprise Ar⁺ ions. This RIE step is analogous to the RIE step 1004 in producing the master-stamp. The overlying photoresist serves to attenuate the ion bombardment, such that a thinner resist thickness will result deeper RIE etching into the robust material.

The result of the RIE step 1108 is robust insulator 1110 which has a grayscale resist thickness profile, disposed on top of the bottom mirror layer. A final step 1112 deposits an upper mirror layer in order to achieve the MIM structure, such that an MSFA optical filter is produced. This final filter 1112 comprising the robust insulator is much more mechanically and thermally robust and the standard resist/polymer layer.

### FURTHER DETAILS AND EXAMPLES

### Dose Variation Parameters

FIG. 12 illustrates three MSFA profiles 1200 show the effect of exposure dose, and moreover how the correct choice of development time (and developer) controls the final thickness of the remaining resist (insulator) in a MIM cavity, hence controlling the center position of the transmission spectra. To demonstrate this, FIG. 12a shows the transmission spectra of a set of 5 μm pixels which vary in exposure dose across three different development times. It can be observed—both quantitatively in (a) and visually in (b)—that for a constant dose range (0.1-0.7 Cm⁻² here) the position of the peak blue-shifts with increasing development time. As the developer is selectively removing resist that has not been sufficiently cross-linked (due to MaN-series photoresist being negative tone), a longer development time results in more resist being removed, hence thinner cavity and shorter wavelength mode. This is further illustrated in profile 1210 in FIG. 12b, which shows a rectangular array with transmission wavelength across the visible spectrum and respective SEM micrograph. An increasing exposure dose (from left to right) was used to generate the array of pixels in the diagram.

### Proximity Effect

In EBL and grayscale EBL, a phenomenon called the proximity effect may arise, and subsequently accounted for in the fabrication of MSFAs. The proximity effect is the unwanted exposure of regions adjacent to the pattern being exposed due to electron scattering events in the resist. In other words, the proximity effect causes the final pixel thickness to be greater in a more densely packed pixel pattern due to the additional exposure from adjacent pixels. The proximity effect can be lessened through the translation of the grayscale MSFA approach to larger batch processing i.e. photolithography. Each filter pixel has its center wavelength defined by a specific exposure dose. As a result of the proximity effect, the total dose applied to a specific region (pixel) is additionally dependent on the dose applied to surrounding pixels. Thus, a pixel's center wavelength may also be defined (to a lesser extent that the dose) by the density with which pixels are arranged.

The proximity effect can be observed by comparing the patterning of isolated pixels (i.e. arrays with non-exposed spacing between pixels) to dense arrays. The dose required to achieve a specific wavelength (resist thickness) may be is lower in dense arrays than it is in isolated regions.

By way of example, FIGS. 4c and 4d show isolated pixels and dense pixel arrays, respectively. Here, the EBL proximity effect leads to variation in the final thickness value, and thus a variation in spectral response, despite an identical dose range. It is observed that the arrays in 4d are red shifted in transmission indicating a larger thickness in remaining resist and thus greater accumulated exposure dose. This is due to the unwanted cumulative adjacent exposure from the neighboring pixels. The final thickness/filtered wavelength is a function of spatial position within the rectangle as the averaged dose density is larger at the center of the rectangle than it is in the corner/edges.

Therefore, an empirical correction may be adopted: to ‘over pattern’ each MSFA, such that the area of interest (image sensor area) is >100 μm from the edge of the MSFA pattern. This approach also demands reducing the dose profile to compensate for increased cumulative exposure in the central region. It is also be possible to perform Monte Carlo electron scattering simulations for each pattern to optimize the dose patterns and avoid this empirical correction.

### Resist Thermal Reflow

The method of producing an MSFA may further comprise applying a technique called thermal reflow. This is a fabrication processing technique that involves the thermal treatment of a photoresist (post-development) such that the resist is brought to a temperature roughly equal to, or slightly above, the glass transition temperature of the resist material. By doing so, the resist ‘reflows’ fully or partially depending on the temperature and time, which results in a smoother resist. The technique, for example, can be used to turn staircase-like 3D-patterns to 3D slopes, or to fabricate microlens (i.e., smooth convex shaped) arrays. For example, thermal reflow may be used to smooth the resist surface post-development (but prior to depositing the second mirror layer) in order to flatten/smooth the second mirror surface, narrowing a FWHM of the spectral response of the MSFA and boosting transmission efficiency.

### Grayscale Lithography Fabrication Example Process

A 1.5 nm Ti adhesion layer is thermally evaporated [Edwards E306 Evaporator] (base pressure ˜2×10⁻⁶ mbar, deposition at 0.1 nm·s⁻¹), followed by a 26 nm layer of Ag (with relatively fast deposition, 0.2-0.3 nm·s⁻¹, for improved optical performance), followed by a second 1.5 nm Ti layer. The first Ti layer promotes adhesion between the glass and Ag, the second increases the wettability of Ag for resist spin-coating and increases chemical stability by reducing Ag oxidation. The optimal thickness of the Ag is determined through simulations trading transmittance against FWHM. The thickness of the Ti layers is such that resist wettability is increased and adhesion is promoted with minimal effect on optical transmittance. MaN-2405 eB resist is spin-coated on top of the samples at 5,200 rpm for 45 s to form a ˜350 nm layer, then baked at 90° C. for 3 min. High voltage (80 kV), high current (4.2 nA) EBL (nB1, Nanobeam Ltd.) is used for the patterning. The bottom metallic mirror layer additionally acts to dissipate accumulated charge during electron beam exposure. The MSFAs have total area dimensions ˜1.1× greater than the image sensor area (4.85 mm diagonal) to correct for the proximity effect (described above) and ensure all sensor pixels are utilized.

The effect of stitching error is reduced due to the rectangular geometry (edges) of the patterns corresponding to the main-field and sub-field fractures. No sample registration marks are used for the samples shown in this study. The high current, in combination with low critical dose (due to inherent high sensitivity) of the resist, allows for fabrication over relatively large areas (millimetres) in quick time periods. The critical parameters in grayscale-to-color fabrication are the exposure dose and development conditions, which are determined empirically through a variety of dose tests, as demonstrated above and in reference to FIG. 12. In the present example (and in FIG. 12) a dose range 5-75 ρC cm⁻² is used and full concentration AZ-726-MIF [AZ Electronic Materials] developer solution for ˜10 s, followed by two DI water (stopper) rinses for 4 min and UHP compressed N₂ blow dry. A post-development bake (90° C. for 30 s)—in which the resist is brought within close proximity to its glass transition temperature—is subsequently performed which yields a smoother surface before the second mirror deposition and improves optical performance. The top-metal, a 26 nm layer of Ag, is thermally evaporated (deposition at 0.2-0.3 nm·s⁻¹) followed by a 12 nm layer of MgF₂. This final capping/encapsulation layer made of MgF₂ adds chemical and mechanical stability to the CFAs and does not detrimentally affect optical properties. In some examples, the encapsulation layer may even improve optical properties.

### Photo-Lithography (PL) Processing Example

SU-8 2000 series negative photoresist [Microchem] is utilized for the wafer-level MSFA processing. It is widely used commercially, has high thermal stability (glass transition temperature>200° C.) and designed to be permanent; typically incorporated into the final processed device. A SUSS Microtec MA/BA6 semi-automated mask aligner, with 365 nm (i-line) exposure and 5× alignment objectives, was operated in hard contact mode. 3 inch double-side polished borosilicate (Borofloat 33) glass wafers [Pi-kem], thickness 500±25 μm are cleaned in successive ultrasonic baths of acetone and IPA for 10 min, rinsed in de-ionized (DI) water, blow-dried with UHP compressed N₂ and dehydrated at 200° C. for 10 minutes.

A set of crosshair alignment markers (30×30 μm) are patterned with PL (500 mJ·cm⁻² exposure) using MaN-1400 series photoresist (2,500 rpm, 50 s; softbake: 95° C., 2 min) and developed with AZ 726 MIF for 3 minutes. The first metallic mirror, composed of Ti/Ag/SiO₂ (1.2/38/12 nm), is deposited on the marker-patterned glass using a Lesker PVD-75 electron beam evaporator (base pressure ˜9×10⁻⁶ mbar, deposition rate 0.5 Å·s⁻¹). During the deposition the wafer chuck is rotated at ˜5 rpm in order to increase coverage uniformity. Lift-off is performed in an ultrasonic bath of N-Methyl-2-pyrrolidone (NMP) at 60° C. for 3 minutes, followed by wafer cleaning (acetone, IPA, DI rinse, N₂ dry, dehydration bake). The resultant wafers have a continuous bottom metallic mirror with a regular array of transparent alignment markers.

SU-8 2000.5 photoresist is spin-coated on top of the wafers at 5,500 rpm for 50 s to form a ˜350 nm layer, then soft-baked at 95° C. for 3 minutes.

FIG. 13 shows another example of a binary amplitude Cr photomask 1032 [JD Photodata] (in addition to the binary mask 902 in FIG. 9) which comprises a repeating array of transparent square pixels, separated by the unit cell 1306 size. A grayscale photomask 914 comprising 9 pixels each having a different degree of opacity is shown, for comparison with the binary mask. Upon exposure in step 916, regions of the resist are chemically activated to the extent to which the exposure is attenuated by the mask.

The binary mask 1302 comprises 1 transmissive (i.e. transparent) pixel per unit square 1306, where the remaining 8/9ths of the mask is opaque, or substantially opaque. Initial exposure of a resist, using the binary mask 1302, results in the structure shown in step 1308. The mask is incrementally translated in steps 1310 and 1312 such that different regions of the resist are exposed. However, in steps 1310 and 1312 a higher energy density of exposure is applied. Thus, the multiple exposures (with different dosages of exposures in 1308, 1310, 1312) using the translated binary mask 1302 may result in exactly the same resultant resist profile as that produced by a single dose exposure with the grayscale mask 1306.

The grayscale mask step advantageously only requires a single exposure step. The binary mask method (1308, 1310, 1312) requires 3 separates exposures of different doses of energy. However, it should be understood that no further cleaning or development step is required in between the exposures in the method of FIG. 13b. The optical performance achieved by both approaches may also be identical. The grayscale mask has the advantage that only a single exposure is required. On the other hand, using the binary mask has the advantage that a less complex mask may be manufactured initially.

For a 30 μm pixels example, the photomask pixels are separated in order to give a final 3×3 (9-band) mosaic, hence 120×120 μm separation. The mask aligner is operated in constant dose and hard contact mode. The mask (with a 3×3 array of alignment crosshairs) is translated above the substrate (e.g. in between steps 1308, 1310, and 1312) (aligned with each band in the 3×3 array and flood exposed; the dose matrix ranges from 10-120 mJ·cm⁻²). A post-exposure bake of 65° C. for 2 minutes is then followed by a 2 minute development in 1-methoxy-2-propanol acetate (PGMEA), IPA rinse and N₂ blow dry. The resultant structure is a bottom metallic mirror with a 3D thickness profile (cavities) across the entire wafer. The second metallic mirror, composed of Ag/SiO₂ (38/38 nm), is deposited using the electron beam evaporator. Custom horizontal and vertical alignment markers are patterned in order to determine the alignment accuracy of the final MSFA pixels.

In the above example, the MSFA was fabricated at the wafer-level. The corresponding resultant transmission spectra of each spectral band spans 460-630 nm, and exhibits excellent optical characteristics, from shortest to longest wavelength: FWHMs of 27, 26, 24, 22, 21, 20, 19, 18, 17 nm (±5 nm) and peak transmission efficiencies of 76, 76, 75, 73, 72, 70, 68, 66, 65% (±6%). The example wafer above also exhibits the narrower 2^{nd} order FP-type resonances (thicker final resist thickness). However, by adjusting the flood exposure dose it is possible to easily incorporate 1^{st} and 2^{nd} order modes, for example by utilizing a different dose matrix for the 3×3 pixel mosaic, which mixes the mode types.

Bespoke wafer-level 9-band MIM-based MSFAs are able to outperform conventional approaches for color filter fabrication, such as plasmonic and high-index dielectric nanostructure arrays/metasurfaces. For example, MSFA transmission bands in the present examples are narrower, have higher transmission efficiencies, exhibit no polarization dependency (up to high angle of incidence chief ray angles). Advantageously, the MSFAs have been fabricated at the wafer level (over large areas), illustrating translation ease to commercial processing.

FIG. 14 shows a photograph of a 3 inch wafer 1400 with ˜32 9-band MSFAs (utilizing 2^{nd} order resonances), with a zoomed in region 1402 captured with a macro lens, which shows a further inset showing the colour profile of the MSFA which has been fabricated atop the wafer according to the above fabrication details, and a corresponding transmission spectrum showing the exact transmission wavelengths of each matrix 1406 on the wafer. An optical micrograph 1404 (transmission) of a different region of the wafer 1400, is shown, in which can be seen the exposure pattern (inset) as fabricated using the dose matrix 1406 also shown. A transmission spectrum 1408 for each spectral band of the 9 transmission wavelengths is shown. Each different wavelength in 1408 corresponds to each of the 9 portions in each repeating 3×3 pattern on the wafer, created as a result of the dose matrix 1406 having 9 different energy doses.

The wafer with overlaid MSFA in FIG. 14 was fabricated using a negative-tone photoresist (SU-8) using the general fabrication process outlined above. As such, the level of exposure corresponds to a greater degree of crosslinking in the photoresist polymer, which results in a thicker cavity layer in each pixel. Therefore, higher doses in the dose matrix 1406 correspond to red-shifted colours in the array 1404, and longer wavelengths as seen in the transmission spectra 1408.

In more detail, a grayscale dose matrix 1406 as shown in FIG. 4 may generally be a 3×3 array (or generally any n×m matrix dimension) where each pixel in the matrix possesses its own dose. The dose matrix may then be applied periodically across an MFSA resist/insulator template using EBL to create a repeating pattern of the matrix over 2 dimensions. Such a dose matrix may be applied using the EBL method described, or alternatively using the mask-based method in which the matrix may be effectively ‘hard-coded’ into an attenuation profile of the mask.

FIG. 15 illustrates box plots of the optical characteristics from a series of MSFA patterns from three different recipes. FIG. 15a shows Peak transmission, FIG. 15b Peak wavelength shift, Δλ, from the average (i.e. Δλ=|λ−λₐᵥ|); and FIG. 15c shows FWHM. The recipes comprise the following:
Recipe 1=pre-development thermal treatment (90° C., 60 s)+normal processing;
Recipe 2=normal processing*;
Recipe 3=normal processing*+post-development thermal treatment (100° C., 30 s).
   *normal processing recipe as described in the preceding examples.

The solid horizontal lines in the centre of each box plot in correspond to the median values, and the bottom and top edges of the box indicate the 25th and 75th percentiles respectively. For every CFA, several unit cells in the middle of each array were picked randomly and the spectrum of each pixel was recorded. For the fewer band (<4) MSFAS, ˜12 spectra were recorded for each recipe. For the larger band MSFAs, 18-27 spectra were recorded for each recipe.

The box plots shows the optical transmission characteristics of a range of MSFA geometries fabricated across three different chips These chips include 2×3-channel designs (RGB1 and RGB2), RGB+1, and 3× different 3×3 mosaics (each with a varying dose profile range).

It can be observed from the plots that the variation in optical performance characteristics is minimal within each respective array. For example, the respective channel peak wavelength shift is typically ≲5 nm across the arrays and different recipes (FIG. 15b). Moreover, it can be concluded from these results that the addition of baking steps to the example protocols described above enhances the peak transmission. As shown in FIG. 15a, adding a post-development bake (Recipe 3) increases the peak-transmission up to around 80%. The FWHM is also improved (FIG. 11c) through adding additional thermal treatment; decreasing to ˜50 nm in comparison to the example protocols described above.

### Pixel Resolution

FIG. 16 shows a series of SEM micrographs of various MIM pixel arrays, including at several resolutions. Array 1600 comprises 1 μm pixel array in which the dose (and thus final insulator thickness) varies in 1D. This 1D dose variation repeats, highlighted by the inset, showing the linear incremental dose increase. Increasing magnifications of the SEM micrograph are shown in arrays 1602 and 1604. The lower arrays 1606, 1608, are fabricated in the same way as the upper three examples of FIG. 16, but with a 500 nm dimension pixel array.

Array 1610 shows a random dose array for 1 μm pixels. Array 1610 is a good illustration of the advantageously versatile fabrication possibilities of the described grayscale lithographic methods. As mentioned previously, any arbitrary optical filter profile may be created merely by modulating the dose profile, and no additional lithographic steps are needed

In some examples, 11 μm×11 μm pixel dimensions are used, primarily due to limitations with the experimental image sensor setup. However, these length scales can be easily reduced using the described methodologies. Arrays may also be fabricated where exposure dose is varied linearly (as in array 1600), with pixel sizes range from: 5.5 μm down to 460 nm (as in 1606, 1608). Further still, 460 nm is not the limit to resolution, and may be reduced even further. Advantageously, the pixel array may still be fabricated to a high degree of uniformity, even at very small <500 nm size scales, as can be seen by the monodisperse pixel dimensions in FIG. 16.

### Optical and Morphological Characterizations

Surface morphology is characterized using an Atomic Force Microscope (AFM) [Asylum Research MFP-3D] in conjunction with Al-reflex-coated Si probes [Budget Sensors, Sigma Aldrich] operated primarily in tapping mode. Scan speed, voltage set-point, and drive amplitude are modified dependent on the feature morphology. Gwyddion software is used for the AFM data visualization and analysis. The raw surface data is plane levelled, scars (strokes) and noise minimized, and the resultant data is presented in 3D topography form. The average height (and standard deviation) of each pixel is obtained using the in-built statistical analysis toolbox. A LEO Gemini 1530VP field emission scanning electron microscope (SEM) operating at 1-5 keV is used for imaging the surface of samples (In-lens operation), which are fixed on angled SEM stubs for non-normal incidence imaging. Carl Zeiss software [SmartSEM] is used to control the SEM and obtain images at several magnifications. The optical characterization is performed using a modified Olympus BX-51 polarizing optical microscope (Halogen light source with IR filters removed) attached via a 300 μm core multi-mode optical fiber [Ocean Optics OP400-2-SR MMF] to a UV-visible spectrometer [Ocean Optics HR2000+] and second optical arm to a digital camera [Lumenera Infinity-2 2MP CCD] for surface imaging. The spectra are normalized to transmission through equivalent thickness borosilicate glass (bright state) and no input light (dark state) using Ocean Optics OceanView software.

For the imaging experiments, the test scene is composed of a Macbeth ColorChecker chart (A5 size) along with a Rubik's cube, which is imaged via a series of lenses through the custom MSFAs onto a CMOS image sensor (Supplementary FIG. 16). A USB 3.0 monochrome 2MP Basler daA1920-30 um area-scan camera is used [Aptina MT9P031 CMOS image sensor], with a total sensor size of 4.2 mm×2.4 mm, resolution of 1920×1080 and 2.2 μm×2.2 μm pixel size. Each filter pixel has dimensions 11 μm×11 μm, corresponding to a 5×5 array of the image sensor pixels. At an image sensor resolution of 1920×1080 the 1:5 trade-off in spatial resolution means the effective resolution of our images is 384×216.

The image sensor is mounted at the end of a custom optical cage-system using a 3D printed [Ultimaker 2+] mount. An in-house built XYZ translation mount holds the MSFAs, which are fabricated on 10 mm×10 mm borosilicate glass chips. The imaging optics consist of three achromatic AR-coated lenses (Thor/abs LSBO8-A series): the first (a concave lens) de-magnifies the scene, the second collimates this virtual image (placed at the focal point of the first lens) and the third focuses the light onto the image sensor, through the MSFA mounted in front of it. An aperture stop is located after the third lens, limiting the range of ray angles impingement on the MSFA and thus onto the image sensor. The MSFAs, fixed in a custom 3D printed mount, are brought close to the borosilicate cover glass (thickness 0.4 mm) of the image sensor. Using the image sensor manual (Micron MT9P031 manual and Basler AW001305 documents) to determine the physical sensor geometry, the minimum distance of the MSFA from the image sensor die (plane) is estimated at ˜0.525±0.05 mm. The MSFA is translated in XYZ in order to align the pixels of the filter array with the pixels of the image sensor. For the MSFA imaging results, a series of optical bandpass filters (Thor/abs FKB-V/S-10 series; 10 nm FWHM) are utilized in a filter wheel mount, backlit with 50 W white light (4000K) floodlight LED array. The reflected light from the object test scene is imaged through the MSFA onto a monochrome image sensor.

### Numerical Simulations

A commercial-grade simulator (Lumerica/FDTD solutions) based on the finite-difference time-domain (FDTD) method was used to perform the calculations. MIM stacks are simulated using a dielectric between two metal layers (z-dimension). Periodic boundary conditions are used (x-y boundaries of the unit cell) and perfectly matched layers (z-boundary) along the direction of propagation. A uniform 2D mesh (Yee-cell) with dimensions nm and broadband-pulse plane-wave (350-1000 nm) injection source at a significant distance (several microns) above the sample are used. For the E-and-H-field intensity plots, an additional finer mesh is included, whereby the smallest cubic mesh size is <0.01 nm (z-direction). Complex dispersive material models are used for Ag (Johnson and Christy model) and SiO₂ (material data), whereas a real-only refractive index of 1.65 is used for MaN-2400 series photoresist (Microchem: Material data sheet) and 1.4 for the transparent Mg F₂ capping/encapsulation layer. Transmittance and reflectance values are calculated from 1D power monitors positioned above the range of structures and source injection.

The skilled person will understand that in the preceding description and appended claims, positional terms such as ‘above’, ‘overlap’, ‘under’, ‘lateral’, ‘vertical’, etc. are made with reference to conceptual illustrations of a filter, such as those showing standard cross-sectional perspectives and those shown in the appended drawings. These terms are used for ease of reference but are not intended to be of limiting nature. These terms are therefore to be understood as referring to an optical filter device when in an orientation as shown in the accompanying drawings.

Although the invention has been described in terms of examples as set forth above, it should be understood that these examples are illustrative only and that the claims are not limited to those examples. Those skilled in the art will be able to make modifications and alternatives in view of the disclosure which are contemplated as falling within the scope of the appended claims. Each feature disclosed or illustrated in the present specification may be incorporated in the invention, whether alone or in any appropriate combination with any other feature disclosed or illustrated herein.

1-33. (canceled)

34. A method for producing an optical filter, the method comprising:
depositing a first mirror layer on a substrate;
depositing an insulating layer on the first mirror layer;
exposing at least some of a plurality of portions of a surface of the insulating layer to a dose of energy;
developing the insulating layer in order to remove a volume from said at least some of the plurality of portions of the insulating layer, wherein the volume of the insulating layer removed from each portion is related to the dose of energy exposed to each portion, and wherein a remaining thickness after the removal of the volume from each portion of the insulating layer is related to the dose of energy exposed to each portion;
depositing a second mirror layer on the remaining thickness of each of the plurality of portions of the insulating layer such that the remaining thickness of each of the plurality of portions of the insulating layer defines a profile of the optical filter.

35. A method as claimed in claim 34, wherein the remaining thickness after the removal of the volume from each portion of the insulating layer is achieved by using a single step lithographic process.

36. A method as claimed in claim 34, wherein the remaining thickness after the removal of the volume from each portion of the insulating layer is achieved by using a grayscale lithographic process.

37. A method as claimed in claim 34, wherein:
the dose of energy is a chemically activating variable dose of energy; and/or
the remaining thickness of each portion of the insulating layer defines a two-dimensional profile of optical wavelengths, optionally wherein said two-dimensional profile of optical wavelengths is an in-plane spatially varying colour profile transmitted through the optical filter.

38. A method as claimed in claim 34, wherein:
the insulating layer is optically transmissive and deposited in a uniform thickness;
the remaining thickness of each portion of the insulating layer defines a spectral position, and wherein a spectrum of light transmitted through each portion of the insulating layer corresponds to the spectral position, optionally wherein a thickness of at least one mirror layer defines a breadth of the transmitted spectrum of light through each portion of the insulating layer.

39. A method as claimed in claim 34, wherein the first mirror layer is partially optically reflective and possesses a first uniform thickness, and wherein the second mirror layer is partially optically reflective and possesses a second uniform thickness.

40. A method as claimed in claim 34, wherein either:
the insulating layer chemically strengthens upon being exposed to the dose of energy; or
the insulating layer chemically weakens upon being exposed to the dose of energy.

41. A method as claimed in claim 34, wherein the dose of energy is exposed to said at least some of the plurality of portions of the insulating layer as a beam of energy which is varied for said at least some of the plurality of portions.

42. A method as claimed in claim 34, further comprising providing a mask over the insulating layer and exposing the mask to a uniform dose of chemically activating energy;
optionally wherein the mask comprises a plurality of portions with variable opacity which attenuate the uniform dose of chemically activating energy to a varying degree, such that a plurality of variably attenuated energy doses are exposed to the insulating layer, optionally wherein the variable opacity of the plurality of portions of the mask defines the remaining thickness of each of the plurality of portions of the insulating layer.

43. A method as claimed in claim 34, further comprising providing an attenuating mask over the insulating layer, the attenuating mask comprising a plurality of portions which defines an attenuation profile, wherein the dose of energy which exposes the surface of the insulating layer is transmitted through the mask and attenuated according to the attenuation profile.

44. A method as claimed in claim 43, wherein:
the plurality of portions of the attenuating mask possesses at least two different levels of opacity; and/or
one of the levels of opacity is opaque or substantially opaque.

45. A method as claimed in claim 43, further comprising laterally translating the mask over the insulating layer and exposing the surface of the insulating layer to a second dose of energy, wherein the second dose of energy is transmitted through the mask and attenuated according to the attenuation profile.

46. A method as claimed in claim 34, further comprising chemically developing the insulating layer, wherein a variable volume from said at least some of the plurality of portions of the insulating layer becomes chemically dissolved and removed from each of the plurality of portions of the insulating layer.

47. A method as claimed in claim 34, further comprising:
depositing a further type insulating layer over the first mirror layer;
depositing the insulating layer on the further type insulating layer;
exposing the at least some of the plurality of portions of the insulating layer to the dose of energy;
etching the remaining thickness of each of the plurality of portions of the insulating layer;
wherein the step of etching the remaining thickness removes a volume from at least some of the plurality of portions of the further type insulating layer;
depositing the second mirror layer on the further type insulating layer.

48. A method as claimed in claim 34, further comprising:
providing a stamping block;
depositing a further insulating layer on the stamping block;
exposing at least some of a plurality of portions of a surface of the further insulating layer to the dose of energy;
developing the further insulating layer in order to remove a volume from said at least some of the plurality of portions of the further insulating layer, wherein the volume of the further insulating layer removed from each portion is related to the dose of energy exposed to each portion, and wherein a remaining thickness after the removal of the volume from each portion of the further insulating layer is related to the dose of energy exposed to each portion;
etching the remaining thickness of each of the plurality of portions of the further insulating layer; and
wherein the step of etching the remaining thickness removes a volume from at least some of the plurality of portions of the stamping block.

49. A method as claimed in claim 48, further comprising applying the developed stamping block on the insulating layer to imprint the remaining thickness of each of the plurality of portions of the insulating layer, optionally wherein the developed stamping block is applied by using additional pressure and/or heat.

50. A method as claimed in claim 34 wherein:
the mirror layers comprise a metal and/or a dielectric material; and/or
the method further comprises depositing a capping layer onto the second mirror layer; and/or
the method further comprises patterning at least one of the mirror layers, wherein the patterning imparts a further characteristic to the transmitted spectrum of light through each portion of the insulating layer; and/or
wherein the substrate is transparent or an image sensor.

51. A method of producing an optical filter, comprising:
providing a stamping block;
depositing a first insulating layer on the stamping block;
exposing at least some of a plurality of portions of a surface of the first insulating layer to a dose of energy;
developing the first insulating layer in order to remove a volume from said at least some of the plurality of portions of the first insulating layer, wherein the volume of the first insulating layer removed from each portion is related to the dose of energy exposed to each portion, and wherein a remaining thickness after the removal of the volume from each portion of the first insulating layer is related to the dose of energy exposed to each portion;
etching the remaining thickness of each of the plurality of portions of the first insulating layer; and
wherein the step of etching the remaining thickness removes a volume from at least some of the plurality of portions of the stamping block.

52. A method as claimed in claim 51, further comprising:
depositing a first mirror layer onto a substrate;
depositing a second insulating layer on the first mirror layer;
applying the stamping block on the second insulating layer to imprint a pattern of the stamping block on the second insulating layer so that portions with variable thicknesses are formed in the second insulating layer;
optionally further comprising depositing a second mirror layer on each of the portions with variable thicknesses formed in the second insulating layer such that the second insulating layer defines a profile of the optical filter.

53. An optical filter device comprising:
a substrate;
a first mirror layer disposed on the substrate;
an insulating layer having a plurality of portions, at least some of the portions having a variable thicknesses;
a second mirror layer disposed on the insulating layer;
wherein the plurality of portions of the insulating layer are manufactured using the method of claim 1.
